(19) United States
(12) Patent Application Publication
(10) Pub. No.: US 2004/0050325 A1
(43) Pub. Date: Mar. 18, 2004

(54) Apparatus and method for delivering process gas to a substrate processing system

(76) Inventors: Arkadii V. Samoilov, Sunnyvale, CA (US); Paul B. Comita, Menlo Park, CA (US)

Correspondence Address: Michael A. Bernadicou, APPLIED MATERIALS, INC., Patent Counsel, Legal Affairs Department, P.O. Box 450A, Santa Clara, CA, 95052, US

(21) Appl. No.: 10/243,377

(22) Filed: Sep. 12, 2002

(51) Int. Cl. C23C 16/00; C23F 1/00

(52) U.S. Cl. 118/715; 156/345.33; 438/14

(57) ABSTRACT

A method and apparatus for delivering process fluids to a substrate processing system is described herein. In one embodiment, the fluid delivery system may include a first conduit for coupling a first fluid to the substrate processing system with a first flow controller for controlling the flow of the first fluid through the first conduit; a second conduit for coupling a second fluid to the substrate processing system with a second flow controller for controlling the flow of the second fluid through the second conduit; and a third conduit for coupling the second fluid to the substrate processing system with a third flow controller for controlling the flow of the second fluid through the third conduit. The fluid delivery system may be used to deliver processing fluids to a substrate processing system during semiconductor fabrication.

### FIELD OF THE INVENTION

The present invention relates generally to the field of semiconductor processing and more specifically to a method and apparatus for delivering process gas to a substrate processing system.

### BACKGROUND OF THE INVENTION

Semiconductor devices such as microprocessors and memories are fabricated by various processes, such as depositing a film on a substrate or etching portions of an existing film on a substrate. Of principal concern in many semiconductor manufacturing processes is the difficulty of maintaining process uniformity. For example, a layer deposited on a substrate may exhibit thickness variations across the substrate as well as composition variations within the deposited layer itself. However, as integrated circuit feature sizes become smaller, it is increasingly important to minimize these variations in order to achieve a deposited layer which exhibits very high thickness and composition uniformities.

Many semiconductor fabrication processes are activated thermally and/or via mass transport. As a result, maintaining optimal process uniformity typically requires adjustments to substrate temperature uniformity and/or gas flow distribution across the surface of the substrate. Prior art semiconductor processing equipment has utilized multi-zone heat sources to adjust the temperature distribution across a substrate in order to compensate for non-uniform mass transport effects. Additionally, prior art semiconductor processing equipment has featured means for distributing process gases according to a desired flow pattern in order to minimize mass transport effects across the surface of a substrate.

Chemical vapor deposition (CVD) processes are commonly used in semiconductor manufacturing to deposit a layer of material onto the surface of a substrate. In an epitaxial silicon-germanium (SiGe) deposition process, doped or undoped silicon-germanium layers are typically deposited onto a substrate using a low-pressure CVD process. In this process, a reactant gas mixture including a source of silicon and germanium is heated and passed over a substrate to deposit a silicon-germanium film on the substrate surface. The silicon source may be monosilane, disilane, dichlorosilane, trichlorosilane, or tetrachlorosilane; the germanium source may be germane. The reactant gas mixture may also include a dopant gas, such as phosphine, arsine or diborane. Other silicon sources, germane sources, and dopants may also be used. In some instances, a non-reactant carrier gas, such as hydrogen, is also injected into the processing chamber, together with either or both of the reactant or dopant gases.

Typically, the temperature dependence of the germanium (Ge) incorporation is reversed as compared to the temperature dependence of the silicon-germanium deposition rate. As a result, simultaneous tuning of the deposited silicon-germanium film thickness and germanium concentration uniformities may be problematic.

In a doped or undoped polysilicon deposition process, the crystallographic nature of the deposited silicon is a function of the deposition temperature. At low reaction temperatures, the deposited silicon is predominantly amorphous. However, when higher deposition temperatures are employed, a mixture of amorphous silicon and polysilicon, or polysilicon alone, is deposited. Additionally, in a doped polysilicon deposition process, the temperature dependence of dopant incorporation into the film is reversed as compared to the temperature dependence of the polysilicon deposition rate. As a result, adjusting the temperature distribution across a substrate to optimize the thickness uniformity of a doped polysilicon layer may result in non-uniform dopant incorporation within the polysilicon layer. In other CVD processes, adjusting the temperature distribution across a substrate may result in detrimental changes to electrical and/or physical properties of a deposited film.

U.S. Pat. No. 5,916,369 to Anderson et al. discloses a method and apparatus for controlling the flow rate and composition of a mixture comprising a silicon source gas and a dopant gas across a substrate surface. Referencing FIG. 2, a gas mixture containing a silicon source and a hydrogen carrier gas is injected into chamber 218 from gas sources 202 and 204. Mass flow controllers 203 and 205 independently control the flow rate of the silicon source and the hydrogen carrier gas to chamber 218. The gas mixture flows through two metering valves 211 and 212 which operate as variable restrictors to apportion the flow of silicon bearing gas between different gas inlet ports of chamber 218. A dopant gas is fed from gas source 214, through mass flow controllers 216 and 220, and into the silicon source and hydrogen carrier gas mixture downstream of metering valves 211 and 212. Mass flow controllers 216 and 220 may be used to independently control the dopant gas concentration flowing into different gas inlet ports of chamber 218.

In Anderson et al., the dopant gas is mixed with the silicon source gas after the silicon source gas passes through metering valves 211 and 212. Metering valves 211 and 212 may be adjusted to alter the apportionment of silicon bearing gas to the gas inlet ports of chamber 218. If such an adjustment occurs, mass flow controllers 216 and 220 may require substantial readjustment and tuning, resulting in excessive system downtime. Additionally, a mass flow controller must be provided to control the flow of each dopant gas at each gas inlet port. In FIG. 2, a single dopant gas is fed into two inlet ports, thereby requiring two mass flow controllers. However, in the case of two dopant gases provided to three gas inlet ports, six mass flow controllers are required, resulting in excessive complexity and high cost of ownership.

Accordingly, a need has arisen for a system of supplying process gases to a semiconductor processing system which overcomes these problems. Such a gas delivery system may be useful in several different fabrication processes such as chemical vapor deposition, physical vapor deposition, etching, thermal annealing, thermal oxidation, and other such processes as are commonly used in the manufacture of integrated circuit devices.

### BRIEF DESCRIPTION OF THE DRAWINGS

The present invention is illustrated by way of example, and not by way of limitation, in the figures of the accompanying drawings.

FIG. 1 is a schematic diagram illustrating one embodiment of an apparatus for delivering process fluids to a substrate processing system.

FIG. 2 is a schematic diagram illustrating one embodiment of an apparatus for delivering process fluids to a substrate processing system.

FIG. 3 is a schematic diagram illustrating one embodiment of a substrate processing system.

FIG. 4 is a schematic diagram illustrating one embodiment of a substrate processing chamber.

FIG. 5 is a schematic diagram illustrating one embodiment of a gas interface adapted to provide gas flow into a process chamber.

FIG. 6 is a schematic diagram illustrating one embodiment of a gas interface adapted to provide gas flow into a process chamber.

FIG. 7 is a schematic diagram illustrating one embodiment of a gas interface adapted to provide gas flow into a process chamber.

FIG. 8 is a schematic diagram illustrating one embodiment of a substrate processing chamber.

FIG. 9 is a schematic diagram illustrating one embodiment of a showerhead adapted to provide gas flow into a process chamber.

FIG. 10 is a schematic diagram illustrating one embodiment of an apparatus for delivering process fluids to a substrate processing system.

FIG. 11 is a schematic diagram illustrating one embodiment of an apparatus for delivering process fluids to a substrate processing system.

FIG. 12A is a graph illustrating thickness uniformity across deposited SiGe layers.

FIG. 12B is a graph illustrating Ge concentration across deposited SiGe layers.

### SUMMARY OF THE INVENTION

A method and apparatus for delivering process fluids to a substrate processing system is described herein. In one embodiment, the fluid delivery system may include a first conduit for coupling a first fluid to the substrate processing system with a first flow controller for controlling the flow of the first fluid through the first conduit; a second conduit for coupling a second fluid to the substrate processing system with a second flow controller for controlling the flow of the second fluid through the second conduit; and a third conduit for coupling the second fluid to the substrate processing system with a third flow controller for controlling the flow of the second fluid through the third conduit. The fluid delivery system may be used to deliver processing fluids to a substrate processing system during semiconductor fabrication.

### DETAILED DESCRIPTION OF THE INVENTION

The present invention describes a method and apparatus for delivering process fluids to a substrate processing system. In the following description, numerous specific details are set forth in order to provide a through understanding of the present invention. One skilled in the art will appreciate that these specific details are not necessary in order to practice the present invention. In other instances, well known equipment features and processes have not been set forth in detail in order to not unnecessarily obscure the present invention.

A processing system having a gas delivery system is described herein. The processing system may include a number of chambers for performing various processes involved in semiconductor fabrication. The processing system may include a process chamber for depositing layers of material onto a surface of a substrate held within the process chamber. The layers may be deposited, for example, by a process such as chemical vapor deposition. During a chemical vapor deposition process, a process gas may be directed into an interior portion of a process chamber and over a surface of a substrate while the temperature of the substrate is maintained at a particular level, such that a layer is formed on the substrate as the process gas passes over the substrate.

A gas delivery system may be used to control the composition and distribution of gases within a process chamber during substrate processing. For example, the gas delivery system may be used to control the concentration and flow rate of one or more process gases flowing over the surface of a substrate during a chemical vapor deposition process, thereby minimizing thickness and composition variations within a deposited layer.

The gas delivery system may direct gases into two or more gas channels contained within an inlet manifold coupled to a process chamber. The gas channels may subsequently direct the gases into an interior portion of the process chamber and across a surface of a substrate. Flow controllers and isolation valves may be used to control the composition and distribution of gases within the gas channels and across the surface of the substrate.

The gas delivery system may provide a gas mixture comprising gases from two or more gas sources to a plurality of gas channels. The composition and flow rate of the gas mixture may be controlled using flow controllers coupled to each gas source. Each flow controller coupled to each gas source may be operated independently of the flow controllers coupled to other gas sources.

The gas delivery system may include a bypass for selectively directing gas from a particular gas source into a gas channel independently of the gas mixture entering that channel. The gas flow rate through the bypass may be controlled using a flow controller coupled to the bypass. As a result, the total flow of gas from a particular gas source may be controlled by two flow controllers: one flow controller may control the gas flow entering the gas mixture and another flow controller may control the gas flow passing through a bypass. Each of the two flow controllers may operate independently of the other flow controller.

The bypass may be coupled to two or more gas channels. The bypass may include an isolation valve for each gas channel coupled to the bypass, and each isolation valve may be used to control the flow of gas from the bypass into a gas channel. Each isolation valve may operate independently of the other isolation valves. Consequently, the bypass may be used to selectively control the flow of a gas into a particular gas channel independently of the flow of gas into other gas channels coupled to the bypass.

The gas delivery system may be structured such that the flow controllers and isolation valves described above are computer controlled flow controllers and isolation valves. A system controller may execute a process recipe which contains settings for controlling the gas delivery system. The system controller may automatically control the computer controlled flow controller and isolation valve setpoints based upon settings contained within the process recipe. Consequently, the gas delivery system may be used to automatically alter the composition and flow rate of gases passing through the gas channels and across different portions of a substrate during processing. The composition and flow rate of gases passing through the gas channels may be altered between steps in a single process recipe or between different process recipes.

The gas delivery system may be used to enhance the control of two or more process gas flows within a process chamber. Alternatively, the gas delivery system may be used to enhance the control of one or more process gas flows and one or more inert gas flows within a process chamber. The gas delivery system may be structured such that the composition and flow rate of gases passing through a particular gas channel may be varied independently of the composition and flow rate of gases passing through other gas channels. Additionally, the gas delivery system may be structured such that the composition and flow rate of gases passing through each gas channel may be varied independently of the composition and flow rate of gases passing through all other gas channels. Consequently, the present invention may provide significant benefits to a wide variety of processes commonly used in the manufacture of electronic devices. For example, in one embodiment the gas distribution system may be integrated with a chemical vapor deposition (CVD) processing system to control the concentration and flow rate of process gases over the surface of a substrate, thereby minimizing mass transport effects during processing and enhancing thickness and/or composition uniformity of a deposited layer. In alternative embodiments, the gas distribution system may be integrated with other types of processes, such as physical vapor deposition (PVD), etch, thermal anneal, thermal oxidation, and others to improve various process parameters.

Processing System

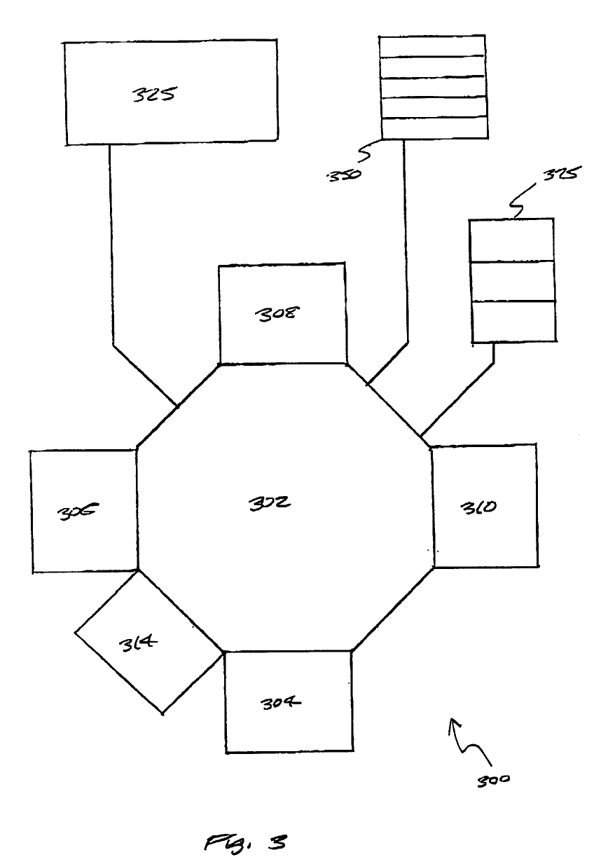

FIG. 3 is a schematic diagram illustrating one embodiment of a substrate processing system 300 having a gas distribution system which is described herein. Processing system 300 may be a cluster processing tool, such as a Centura or Endura processing system manufactured by Applied Materials of Santa Clara, Calif. Processing system 300 may include one or more load-lock chambers 304, one or more process chambers 306, 308, and 310, and a cooldown chamber 314 attached to a central transfer chamber 302. Processing system 300 may further include a system controller 325 for controlling various operations of processing system 300, power supplies 350 for supplying various forms of energy to processing system 300, and pumps 375 for evacuating various vacuum chambers contained within processing system 300.

System controller 325 may control the operation of processing system 300, including the operation of load-lock chambers 304; process chambers 306, 308, and 310; metrology chamber 312; cooldown chamber 314; central transfer chamber 302; power supplies 350; and pumps 375. System controller 325 may also control the operation of computer controlled mass flow controllers and isolation valves structured to the computer controlled gas delivery system.

System controller 325 may include a single board computer (SBC) comprising a processor and memory. The SBC processor may include a central processing unit (CPU) such as a Pentium microprocessor manufactured by Intel Corporation of Santa Clara, Calif. In some embodiments, the SBC processor may include an application specific integrated circuit (ASIC) to operate one or more specific components of processing system 300. For example, the SBC processor may include an ASIC to operate computer-controlled mass flow controllers. The SBC memory may include various volatile and non-volatile memory devices, such as RAM or EPROMs.

System controller 325 may also include one or more memory storage devices, such as a hard disk drive, a floppy disk drive, or a CD-ROM drive. System controller 325 may further include one or more input/output (I/O) devices, such as a CRT monitor and keyboard; analog input/output boards; digital input/output boards; interface boards; and stepper motor controller boards. The SBC processor, SBC memory, memory storage devices, and input/output devices may communicate via a communications bus.

System controller 325 may control all of the activities of the processing system 300 according to an instruction set defined by system control software. The system control software may be stored in a computer-readable medium and executed by system controller 325. Preferably, system control software is stored on a hard disk drive, but system control software may also be stored on a floppy disk, RAM, a CD-ROM or other types of memory storage devices. The system control software may be written in any conventional programming language, including but not limited to 68000 assembly language, C, C++, Pascal, or Fortran. In a preferred embodiment, the system control software comprises Legacy software developed by Applied Materials of Santa Clara, Calif.

The system control software typically contains instructions for managing all operational aspects of processing system 300. For example, the system control software may include a chamber manager subroutine for controlling the various chamber components necessary to carry out a particular process on a substrate, such as process gas control valves, susceptor positioning actuators, and power supplies. In operation, the chamber manager subroutine may monitor the various chamber components, determine which components need to be operated based on the process parameters for the process set to be executed, and direct the control of those components responsive to the monitoring and determining steps. The system control software may manage other operational aspects of processing system 300, such as the movement of wafer transfer mechanisms and the opening and closing of vacuum pump valves.

Instructions for directing a chamber to perform a specific process on a substrate may be contained within a process recipe which is stored in memory and executed by the SBC processor. A process recipe may comprise one or more sequential process steps. Each process step may contain a set of variables that dictate various process parameters for that recipe step, such as step duration, gas flow, chamber pressure, substrate temperature, power supply output, and susceptor position. Process parameters may be changed between process steps to vary the processing environment within a process chamber. To execute a process recipe, the process recipe is read into SBC memory and executed by the SBC processor to perform the tasks identified within the process recipe steps.

Instructions for directing processing system 300 to perform a series of processes on a substrate are contained within a process sequence. Like the system control software and process recipe, a process sequence may be stored in a computer-readable medium such as a memory. A process sequence may direct processing system 300 to perform a series of processes on a substrate in several different chambers within processing system 300. For example, a process sequence may direct process system 300 to transfer a wafer from load-lock chamber 304 to process chamber 306. The sequence may then direct process chamber 306 to perform a first process on the wafer as governed by a first process recipe. The sequence may then direct process system 300 to transfer the wafer from process chamber 306 to process chamber 308 in order to perform a second process on the wafer as governed by a second process recipe. The process sequence may then direct processing system 300 to transfer the wafer to cooldown chamber 314 to be processed according to a cooldown recipe. Finally, the process sequence may direct processing system 300 to return the wafer to load-lock chamber 304.

A process sequence may be assigned to each substrate in a lot of substrates prior to processing. Each substrate within a lot of substrates may be assigned the same process sequence, in which case each substrate is processed identically within processing system 300. Alternatively, substrates within a lot of substrates may be assigned different process sequences, in which case substrates within the lot of substrates are processed differently according to their assigned process sequence.

Prior to performing a process sequence, a lot of wafers is placed within load-lock chamber 304. The atmosphere within load-lock chamber 304 is subsequently evacuated, thereby removing a majority of atmospheric gases from the interior of load-lock chamber 304. Upon initiating a process sequence, a wafer transfer robot located within transfer chamber 302 sequentially transfers wafers to a series of chambers as defined in the process sequence. For example, the transfer robot may transfer a wafer to an orienter chamber; one or more process chambers 306, 308, and 310; a cooldown chamber 314; and then back to load-lock chamber 304. Process chambers 306, 308, and 310 may perform various processes on the wafer as required, such as deposition, etching, or annealing. Cooldown chamber 314 may be used to cool each wafer before returning the wafer to load-lock chamber 304. After the lot of wafers has been processed, load-lock chamber 304 may be vented to atmospheric pressure, opened, and the wafers may be removed for subsequent processing in other wafer processing systems.

Process Chamber

Referencing FIG. 3, process chambers 306, 308, and 310 may include a process chamber used to deposit layers over a substrate. The layers may be deposited by numerous processes such as chemical vapor deposition (CVD), physical vapor deposition (PVD), or other such processes as are commonly used in the fabrication of electronic devices. The gas distribution system of the present invention may be incorporated into a variety of substrate processing systems in order to enhance the control of two or more process gas flows within a process chamber. For example, the gas distribution system may be integrated with a chemical vapor deposition (CVD) processing system to control the flow of process gases over the surface of a substrate, thereby enhancing thickness and/or composition uniformity of a deposited layer. Alternatively, the gas distribution system may be used to enhance the control of one or more process gases flows and one or more inert gas flows within a process chamber. In the present invention, a process gas is defined as a gas or gas mixture which acts to deposit, remove, or treat a film on a substrate placed in a processing chamber. An inert gas is defined as a gas which is substantially non-reactive with chamber features and substrates placed in a deposition chamber at particular process temperatures.

For illustrative purposes, the gas distribution system of the present invention will be described herein in reference to a CVD processing system. However, the gas distribution system may also be integrated with a physical vapor deposition (PVD) processing system, an etch processing system, or any of a variety of other substrate processing systems as are commonly used in the manufacture of electronic devices. In a typical CVD process, a process gas is passed through a process chamber and over a substrate. The substrate is maintained at a particular temperature such that a layer is formed on the substrate as the process gas passes over the substrate.

CVD Process Chamber with Side Gas Injection

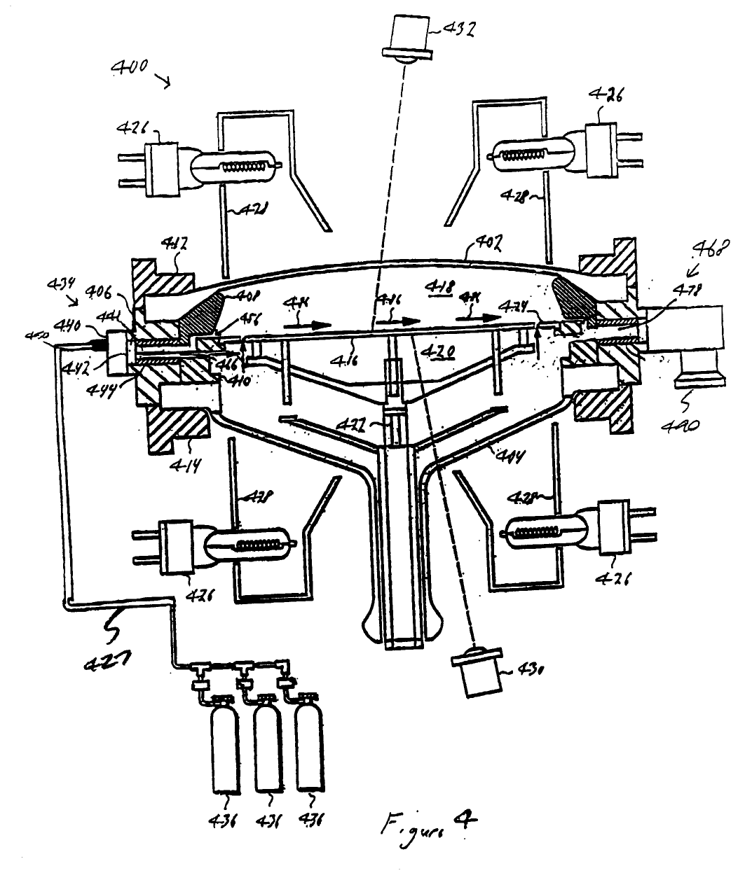

FIG. 4 is a schematic diagram illustrating one embodiment of a CVD process chamber 400. Process chamber 400 may be substantially similar to process chambers 306, 308, and/or 310 described above in reference to FIG. 3. Process chamber 400 may include an upper dome 402, a lower dome 404, and a sidewall 406 positioned between upper dome 402 and lower dome 404. Cooling fluid may be circulated through sidewall 406 to cool o-rings which seal upper dome 402 and lower dome 404 to sidewall 406. An upper liner 408 and a lower liner 410 may be mounted against an inside surface of sidewall 406. Upper dome 402 and lower dome 404 may be formed from a transparent material to allow heating light to pass through into process chamber 400. An upper clamping ring 412 may extend around the periphery of an outer surface of upper dome 402. A lower clamping ring 414 may extend around the periphery of an outer surface of lower dome 404. Upper clamping ring 412 and lower clamping ring 414 may be secured together so as to clamp upper dome 402 and lower dome 404 to sidewall 406.

A susceptor 416 may be located within process chamber 400. Susceptor 416 may be adapted to removeably support a wafer in an approximately horizontal position. Susceptor 416 may extend transversely across process chamber 400 to divide process chamber 400 into an upper portion 418 above susceptor 416, and a lower portion 420 below susceptor 416. Susceptor 416 may be mounted on a shaft 422 that extends vertically downward from the center of the bottom surface of susceptor 416. Shaft 422 may be connected to a motor that rotates shaft 422 and thereby rotates susceptor 416 and a wafer supported by susceptor 416. An annular preheat ring 424 may be connected at its outer periphery to the inner periphery of lower liner 410 and may extend around susceptor 416. Annular preheat ring 424 may be in the same plane as susceptor 416, with the inner periphery of annular preheat ring 424 separated by a gap from the outer periphery of susceptor 416.

In one embodiment, a plurality of lamps 426 may be mounted around process chamber 400. Reflectors 428 may be located around lamps 426 to prevent energy radiated by lamps 426 from radiating away from process chamber 400. Reflectors 428 may also be formed to reflect radiant energy towards upper dome 402 and lower dome 404. Lamps 426 may radiate energy through the upper dome 402 and lower dome 404 to heat susceptor 416 and annular preheat ring 424. Upper dome 402 and lower dome 404 may be made of a transparent material, such as quartz, so that energy radiated by lamps 426 may pass through upper dome 402 and lower dome 404. In other embodiments, heating devices other than lamps, such as resistance heaters or RF inductive heaters, may be used to heat susceptor 416 and annular preheat ring 424.

Susceptor 416 and annular preheat ring 424 may be formed from a material that is opaque to radiation emitted by lamps 426, such as silicon carbide coated graphite. Thus, susceptor 416 and annular preheat ring 424 may be more readily heated by energy radiated from lamps 426. A lower infrared temperature sensor 430, such as a pyrometer, may be mounted below lower dome 404, and may face the bottom surface of susceptor 416 through lower dome 404. Lower infrared temperature sensor 430 may be used to monitor the temperature of susceptor 416 by receiving infrared radiation emitted from susceptor 416 when susceptor 416 is heated. An upper infrared temperature sensor 432 may be mounted above upper dome 402 facing the top surface of susceptor 416 through upper dome 402. Upper infrared temperature sensor 432 may be used to monitor the temperature of a wafer supported by susceptor 416.

Process chamber 400 may be a “cold wall” reactor wherein sidewall 406, upper liner 408, and lower liner 410 are at a substantially lower temperature than preheat ring 424 and susceptor 416 during processing. For example, in a process to deposit an epitaxial silicon film on a wafer, susceptor 416 and a wafer supported by susceptor 416 may be heated to a temperature of between 400-1200° C. The sidewall and liners may be maintained at a lower temperature of approximately 200-600° C. by cooling fluid circulated through sidewall 406.

Process chamber 400 may include a gas interface 434 positioned in a side of process chamber 400. Gas interface 434 may be adapted to transmit gases from one or more gas sources 436 into process chamber 400. Gas sources 436 may include process gases and inert gases. Gas interface 434 may include a connector cap 440, a baffle 442, and an insert plate 444 positioned within sidewall 406. Upper and lower fluid conduits 441 and 466 may be formed in connector cap 440 and insert plate 444. Process chamber 400 may further include a passage 456 formed between upper liner 408 and lower liner 410. Passage 456 may be fluidly connected to upper portion 418 of process chamber 400. Process gas from gas sources 436 may pass through connector cap 440, baffle 442, insert plate 444, and passage 456 into upper portion 418 of process chamber 400.

As shown in FIG. 4, gas sources 436 may be connected to gas interface 434 by gas supply conduit 427. However, typically, each gas source has an independent gas supply conduit from the gas source to a gas distribution panel located on or adjacent to processing system 300. Additional gas supply conduits may be structured to connect gas interface 434 to the gas distribution panel. Consequently, gases from gas sources 436 may be directed to a gas distribution panel which subsequently directs the gases to gas interface 434.

During operation, one or more gases are supplied to gas interface 434 by means of inlet ports 450. Gases from inlet ports 450 flow through connector cap 440 and bank against the upstream surface of baffle 442. The gases are directed through holes formed in baffle 442 into upper and lower conduits 441 and 466 formed in insert plate 444. Inlet ports 450, connector cap 440, baffle 442, and upper and lower conduits 441 and 466 may form independent flow pathways for each gas entering process chamber 400. As a result, each gas flowing into each inlet port and through connector cap 440, baffle 442, and insert plate 444 along upper and lower conduits 441 and 466 may be kept separate from other gases entering process chamber 400. From upper conduits 441, gases may flow across preheat ring 424, susceptor 416 and a wafer supported by susceptor 416 in the direction indicated by arrows 486. The gas flow profile from upper conduits 441, across preheat ring 424 and a wafer may be predominantly laminar.

In one embodiment, process gases from lower conduits 466 and upper conduits 441 may both be directed into upper portion 418 of process chamber 400. In an alternative embodiment, an inert gas may be directed through lower conduits 466 into lower portion 420 of process chamber 400. For example, an inert purge gas such as hydrogen or nitrogen may be directed into lower portion 420 of process chamber 400 in order to prevent deposition on the back side of susceptor 416. An inert purge gas may be fed into lower portion 420 at a rate which develops a positive pressure within lower portion 420 with respect to the process gas pressure in upper portion 418, thereby preventing process gas from entering lower portion 420.

Gases entering process chamber 400 from upper and lower conduits 441 and 466 may be evacuated from process chamber 400 through outlet 468. Outlet 468 may be positioned in the side of process chamber 400 opposite gas interface 434. Outlet 468 may include an exhaust passage 478 which extends from the upper chamber portion 418 to the outside diameter of sidewall 406. Exhaust passage 478 may be coupled to outlet connector 490 on the exterior of sidewall 406. Outlet connector 490 may be coupled to a vacuum source, such as a pump, by means of an exhaust foreline. The vacuum source may be used to create low or reduced pressure in chamber 400 during processing. Thus, process gas fed into process chamber 400 may be evacuated through exhaust passage 478 and outlet connector 490 into an exhaust foreline.

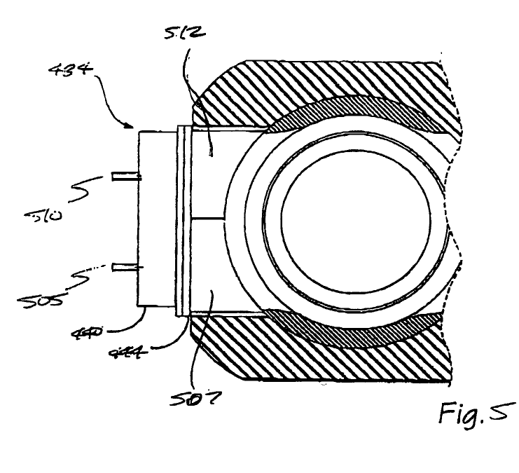

FIG. 5 illustrates one embodiment of gas interface 434 adapted to provide two gas flow channels into upper portion 418 of process chamber 400. In this embodiment, gas interface 434 may include a first inlet port 505 and a second inlet port 510 connected to a first channel 507 and a second channel 512, respectively. During substrate processing, a first gas flow entering first inlet port 505 may flow through first channel 507 and across a first portion of a substrate positioned on susceptor 416. Similarly, a second gas flow entering second inlet port 510 may flow through second channel 512 and across a second portion of the substrate.

In one embodiment, the composition of the gas mixture entering first channel 507 may be controlled independently of the composition of the gas mixture entering second channel 512. Consequently, the composition of gas mixtures flowing across first and second portions of a substrate positioned on susceptor 416 may be varied to more accurately control the uniformity of a layer deposited on the substrate. For example, the gas flow passing through first channel 507 may contain a higher concentration of a gas than the gas flow passing through second channel 512 in order to increase the thickness uniformity of a particular deposited layer. Alternatively, the gas flow passing through first channel 507 may contain a lower concentration of a gas than the gas flow passing through second channel 512.

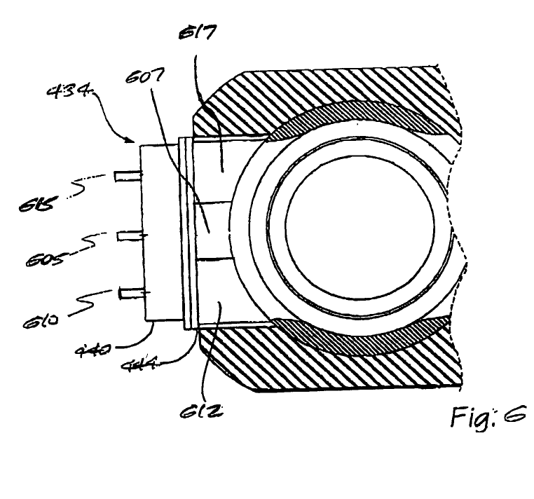

FIG. 6 illustrates another embodiment of gas interface 434 adapted to provide three gas flow channels into upper portion 418 of process chamber 400. In this embodiment, gas interface 434 may include a central inlet port 605, a first outside inlet port 610, and a second outside inlet port 615 connect to a central channel 607, a first outside channel 612, and a second outside channel 617, respectively. During substrate processing, a first gas flow entering central inlet port 605 may flow through central channel 607 and across a central portion of a substrate positioned on susceptor 416. A second gas flow entering first outside inlet port 610 may flow through first outside channel 612 and across a first outside portion of the substrate. And a third gas flow entering second outside inlet port 615 may flow through second outside channel 617 and across a second outside portion of the substrate.

In one embodiment, the composition of the gas mixture entering central channel 607 may be controlled independently from the composition of the gas mixture entering first outside channel 612 and second outside channel 617. Consequently, the composition of the gas mixture flowing across the central portion of a substrate positioned on susceptor 416 may be varied with respect to the composition of the gas mixtures flowing across the first and second outside portions of the substrate to more accurately control the uniformity of a layer deposited on the substrate. For example, the gas flow passing through central channel 607 may contain a higher concentration of a gas than the gas flow passing through first outside channel 612 and second outside channel 617 in order to increase the thickness uniformity of a particular deposited layer. Alternatively, the gas flow passing through central channel 607 may contain a lower concentration of a gas than the gas flow passing through first outside channel 612 and second outside channel 617.

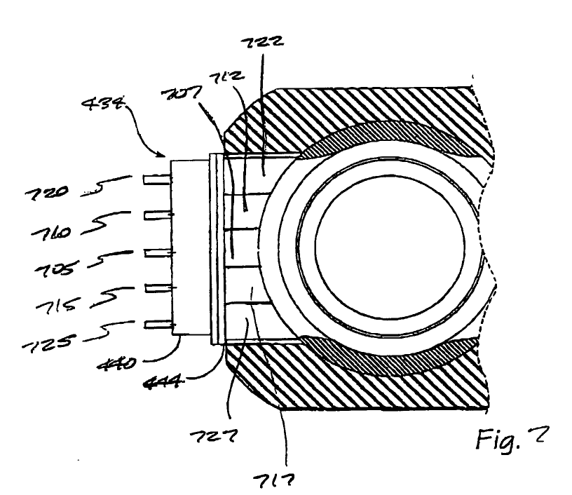

FIG. 7 illustrates yet another embodiment of gas interface 434 adapted to provide five gas flow channels into upper portion 418 of process chamber 400. In this embodiment, gas interface 434 may include a central inlet port 705, a first middle inlet port 710, a second middle inlet port 715, a first outside inlet port 720, and a second outside inlet port 725 connected to a central channel 707, a first middle channel 712, a second middle channel 717, a first outside channel 722, and a second outside channel 727, respectively. During substrate processing, a first gas flow entering central inlet port 705 may flow through central channel 707 and across a central portion of a substrate positioned on susceptor 416. A second gas flow entering first middle inlet port 710 may flow through first middle channel 712 and across a first middle portion of the substrate. A third gas flow entering second middle inlet port 715 may flow through second middle channel 717 and across a second middle portion of the substrate. A fourth gas flow entering first outside inlet port 720 may flow through first outside channel 722 and across a first outside portion of the substrate. A fifth gas flow entering second outside inlet port 725 may flow through second outside channel 727 and across a second outside portion of the substrate.

In one embodiment, the composition of the gas mixture entering central channel 707 may be controlled independently of the composition of the gas mixtures entering first middle channel 712, second middle channel 717, first outside channel 722, and second outside channel 727. Similarly, the composition of the gas mixtures entering first middle channel 712 and second middle channel 717 may be controlled independently of the composition of the gas mixtures entering central channel 707, first outside channel 722, and second outside channel 727. Additionally, the composition of the gas mixtures entering first outside channel 722, and second outside channel 727 may be controlled independently of the composition of the gas mixtures entering central channel 707, first middle channel 712, and second middle channel 717.

Consequently, the composition of a gas mixture flowing across the central portion of a substrate positioned on susceptor 416 may be varied with respect to the composition of the gas mixtures flowing across the first middle, second middle, first outside, and second outside portions of the substrate; the composition of the gas mixtures flowing across the first middle and second middle portions of the substrate may be varied with respect to the composition of the gas mixtures flowing across the central, first outside, and second outside portions of the substrate; and the composition of the gas mixtures flowing across the first outside and second outside portions of the substrate may be varied with respect to the composition of the gas mixtures flowing across the central, first middle, and second middle portions of the substrate to more accurately control the uniformity of a layer deposited on the substrate.

For example, the gas flow passing through central channel 707 may contain a higher concentration of a gas than a gas flow passing through first middle channel 712, second middle channel 717, first outside channel 722, and second outside channel 727 in order to increase the thickness uniformity of a particular deposited layer. Alternatively, the gas flow passing through central channel 707 may contain a lower concentration of a gas than a gas flow passing through first middle channel 712, second middle channel 717, first outside channel 722, and second outside channel 727. The gas flow passing through first middle channel 712 and second middle channel 717 may similarly contain a higher or lower concentration of a gas than the gas flows passing through central channel 707 and/or first outside channel 722 and second outside channel 727. And the gas flow passing through first outside channel 722 and second outside channel 727 may similarly contain a higher or lower concentration of a gas than the gas flows passing through central channel 707 and/or first middle channel 712 and second middle channel 717.

The embodiments illustrated in FIGS. 5, 6, and 7 should not be interpreted as limiting as one of ordinary skill in the art will recognize that gas interface 434 may be structured to provide any number of gas flow channels into upper portion 420 of process chamber 400. Additionally, the described gas flows and comparative gas concentrations are merely exemplary and other gas flows and concentrations may be directed to different gas flow channels as required for particular processes.

CVD Process Chamber with Showerhead Gas Injection

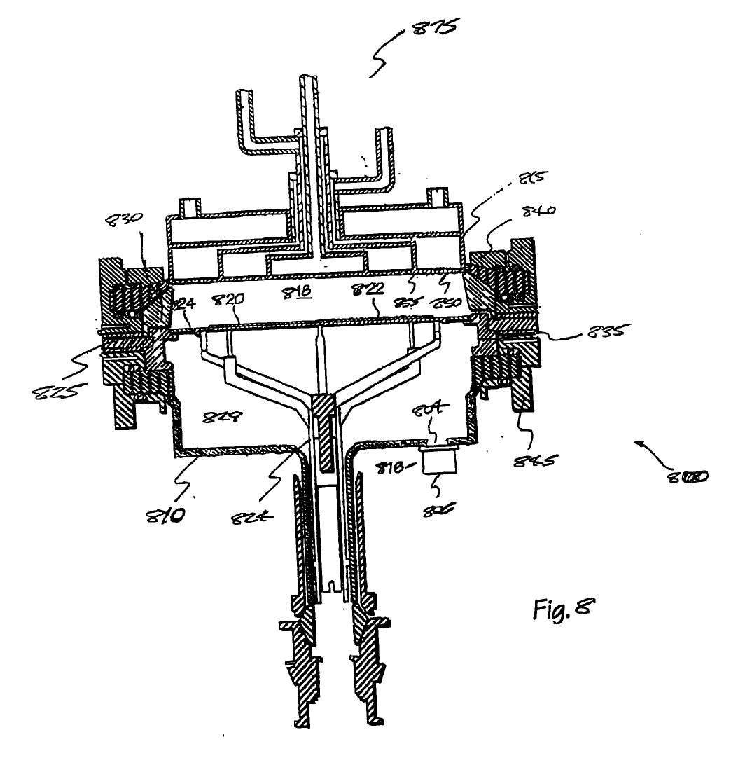

FIG. 8 illustrates process chamber 800, an alternative embodiment of a CVD process chamber. Process chamber 800 may be substantially similar to process chambers 306, 308, and/or 310 described above in reference to FIG. 3. Process chamber 800 may include showerhead 815, lower chamber wall 810, and a sidewall 825 between showerhead 815 and lower chamber wall 810. Cooling fluid may be circulated through sidewall 825 to cool o-rings which seal showerhead 815 and lower chamber wall 810 to sidewall 825. An upper liner 830 and a lower liner 835 may be mounted against an inside surface of sidewall 825. An upper clamping ring 840 may extend around the periphery of an outer surface of showerhead 815. A lower clamping ring 845 may extend around the periphery of an outer surface of lower chamber wall 820. Upper clamping ring 840 and lower clamping ring 845 may be secured together so as to clamp showerhead 815 and lower chamber wall 810 to sidewall 825.

A susceptor 822 may be located within process chamber 800. Susceptor 822 may be adapted to removeably support wafer 820 in an approximately horizontal position. Susceptor 822 may extend transversely across process chamber 800 to divide process chamber 800 into an upper portion 818 above susceptor 822, and a lower portion 828 below susceptor 822. Susceptor 822 may be mounted on a shaft 824 that extends vertically downward from the center of the bottom surface of susceptor 822. An annular preheat ring 824 may be connected at its outer periphery to the inner periphery of lower liner 835 and may extend around susceptor 822. Annular preheat ring 824 may be in the same plane as susceptor 822, with the inner periphery of annular preheat ring 824 separated by a gap from the outer periphery of susceptor 822. In one embodiment, susceptor 822 and annular preheat ring 824 may be heated by means of a resistance heater contained within susceptor 822. In other embodiments, RF inductive heaters, lamps, or other such heating devices may be used to heat susceptor 822 and annular preheat ring 824. The temperature of susceptor 822 may be monitored by means of a thermocouple embedded within susceptor 822.

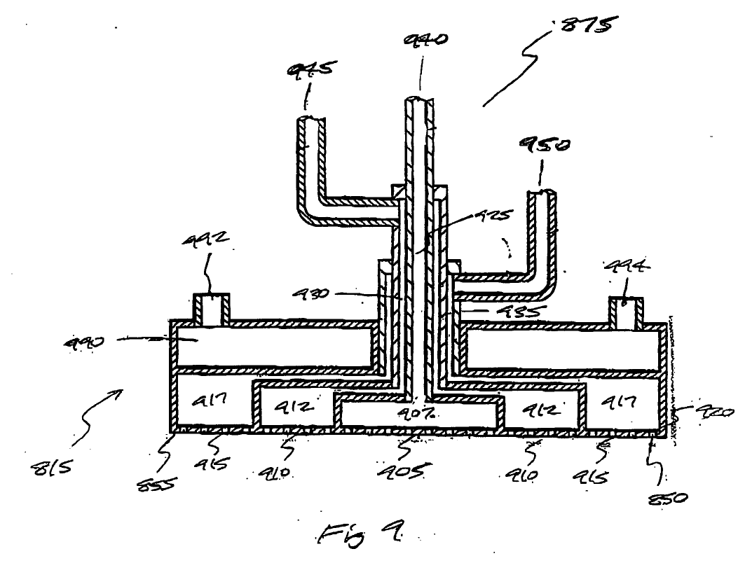

One or more process gases may be injected into upper portion 818 of process chamber 800 through a plurality of orifices 850 extending through a lower surface 855 of showerhead 815. Orifices 850 may be arranged in a plurality of regions or zones on lower surface 855 of showerhead 815. As shown in FIG. 9, orifices 850 may be arranged in a center region 905, a middle region 910, and an outer region 915. Middle region 910 may be arranged in an annular configuration encircling center region 905 and outer region 915 may be arranged in an annular configuration encircling middle region 910 and extending adjacent to an outer periphery 920 of showerhead 815.

Showerhead 815 may further include center passageway 907, middle passageway 912 and outer passageway 917. Orifices contained within center region 905 of showerhead 815 may connect with center passageway 907. Similarly, orifices contained within middle region 910 may connect with middle passageway 912. In like fashion, orifices contained within outer region 915 may connect with outer passageway 917.

Process chamber 800 may further include a gas interface 875 positioned in a top portion of process chamber 800 and connected to showerhead 815. Gas interface 875 may be adapted to direct gas from one or more gas sources through showerhead 815 and into upper portion 818 of process chamber 800. Referencing FIG. 9, gas interface 875 may include center conduit 925, middle conduit 930, and outer conduit 935. Center passageway 907 may be connected to center conduit 925; middle passageway 912 may be connected to middle conduit 930; and outer passageway 917 may be connected to outer conduit 935. Center conduit 925 may be arranged coaxially along a portion of middle conduit 930 and outer conduit 935. Similarly, middle conduit 930 may be arranged coaxially along a portion of outer conduit 935.

Gas interface 875 may further include center inlet port 940, middle inlet port 945, and outer inlet port 950. Center inlet port 940, middle inlet port 945, and outer inlet port 950 may be structured and arranged to provide process gas from one or more gas sources to gas interface 875. Center inlet port may be connected to center conduit 925; middle inlet port 945 may be connected to middle conduit 930; and outer inlet port 950 may be connected to outer conduit 935. Center inlet port 940, middle inlet port 945, and outer inlet port 950 may be connected to one or more gas supply lines, which are in turn connected to gas sources, such as gas cylinders.

As in the previous embodiment, process chamber 800 may be a “cold wall” reactor wherein sidewall 825, upper liner 830, and lower liner 835 are at a substantially lower temperature than preheat ring 824 and susceptor 822 during processing. Additionally, one or more channels 990 having an inlet 992 and an outlet 994 may be formed in showerhead 815. A fluid may be directed into inlet 992, through channels 990, and out of outlet 994 to heat or cool showerhead 815 during operation of process chamber 800.

In operation, one or more gases may be supplied to gas interface 875 through center inlet port 940, middle inlet port 945, and outer inlet port 950. Gas from center inlet port 940 may flow through center conduit 925, center passageway 907, and orifices in center region 905 into upper portion 818 of process chamber 800. Gas from middle inlet port 945 may flow through middle conduit 930, middle passageway 912, and orifices in middle region 910 into upper portion 818 of process chamber 800. Gas from outer inlet port 950 may flow through outer conduit 935, outer passageway 917, and orifices in outer region 915 into upper portion 818 of process chamber 800. Inlet ports 940, 945, and 950; conduits 925, 930, and 935; and passageways 907, 912, and 917 may form independent flow pathways for each gas entering process chamber 800. As a result, each gas flowing into each inlet port and through each conduit and passageway may be kept separate until the gases enter upper portion 818 of process chamber 800.

Gases entering process chamber 800 from showerhead 815 may be evacuated from process chamber 800 through outlet 816. Outlet 816 may be formed in lower chamber wall 810 of process chamber 800. Outlet 816 may include an exhaust passage 804 which extends from lower chamber portion 828 to the lower surface of lower chamber wall 810. Exhaust passage 804 may be coupled to outlet connector 806 on the exterior of lower chamber wall 810. Outlet connector 806 may be coupled to a vacuum source, such as a pump, by means of an exhaust foreline. The vacuum source may be used to create low or reduced pressure in chamber 800 during processing. Thus, process gas fed into process chamber 800 may be evacuated through exhaust passage 804 and outlet connector 806 into an exhaust foreline.

Gas entering center inlet port 940 may initially contact a central portion of a substrate positioned on susceptor 416; gas entering middle inlet port 945 may initially contact a middle annular portion of the substrate; and gas entering outer inlet port 950 may initially contact an outer annular portion of the substrate. After entering upper portion 818 of process chamber 800, process gases may flow radially across wafer 820, susceptor 822, and preheat ring 824.

In one embodiment, the composition of the gas mixtures entering center inlet port 940 and outer inlet port 945 may be controlled independently from the composition of the gas mixtures entering middle inlet port 945. Consequently, the composition of the gas mixtures flowing across the central and outer annular portions of a substrate positioned on susceptor 822 may be varied with respect to the composition of the gas mixtures flowing across the middle annular portion of the substrate to more accurately control the uniformity of a layer deposited on the substrate. For example, the gas flows passing through center inlet port 940 and outer inlet port 945 may contain a higher concentration of a gas than the gas flow passing through middle inlet port 945 in order to increase the thickness uniformity of a particular deposited layer.

FIG. 8 should not be interpreted as limiting as one of ordinary skill in the art will recognize that gas interface 875 may be structured to provide any number of gas flow channels into upper portion 818 of process chamber 800. Additionally, the described gas flows and gas concentrations are merely exemplary and other gas flows and concentrations may be directed to different gas flow channels as required for particular processes.

Gas Delivery System

As previously discussed, a process chamber may include a gas interface adapted to provide multiple gas flow channels to an interior portion of a process chamber. For example, FIG. 5 illustrates one embodiment of gas interface 434 adapted to provide two gas flow channels, FIG. 6 illustrates another embodiment of gas interface 434 adapted to provide three gas flow channels, and FIG. 7 illustrates yet another embodiment of gas interface 434 adapted to provide five gas flow channels. Similarly, FIG. 9 illustrates an embodiment of a gas interface 875 adapted to provide three gas flow regions within process chamber 800.

In each of these examples, a gas delivery system may be arranged to direct one or more gases into each gas flow channel. The gas delivery system may provide a mixture of gases from two or more gas sources to the channels. The composition and flow rate of the mixture of gases may be controlled using flow controllers coupled to each gas source. Each flow controller coupled to each gas source may be operated independently of the flow controllers coupled to other gas sources.

The gas delivery system may include a bypass for selectively directing gas from a particular gas source into a gas channel independently of the gas mixture entering that channel. The gas flow rate through the bypass may be controlled using a flow controller coupled to the bypass. The bypass may be coupled to two or more gas channels, and the bypass may include an isolation valve for each gas channel coupled to the bypass. Each isolation valve may be operated independently from other bypass isolation valves. As a result, gas from the bypass may be selectively directed into each gas channel. Hence, the bypass may be used to selectively control the flow of a gas into a particular gas channel independently of the flow of gas into other gas channels coupled to the bypass.

In one embodiment, the gas delivery system may allow the composition and flow rate of gases passing through a particular gas flow channel to be varied independently of the composition and flow rate of gases passing through other gas flow channels. In another embodiment, the gas delivery system may allow the composition and flow rate of gases passing through each gas flow channel to be varied independently of the composition and flow rate of gases passing through all other gas flow channels. In some embodiments, the flow controllers and isolation valves described above may be computer controlled flow controllers and computer controlled isolation valves.

In the following descriptions, the term “manifold” is generally used to describe a plurality of conduits arranged to combine two or more fluid flow inlets into a single fluid flow outlet, or a plurality of conduits arranged to divide a single fluid flow inlet into two or more fluid flow outlets. Fluid flow conduits used to construct a manifold may be formed from a variety of materials as are commonly employed in semiconductor manufacturing systems, such as stainless steel gaslines.

Gas Delivery System I

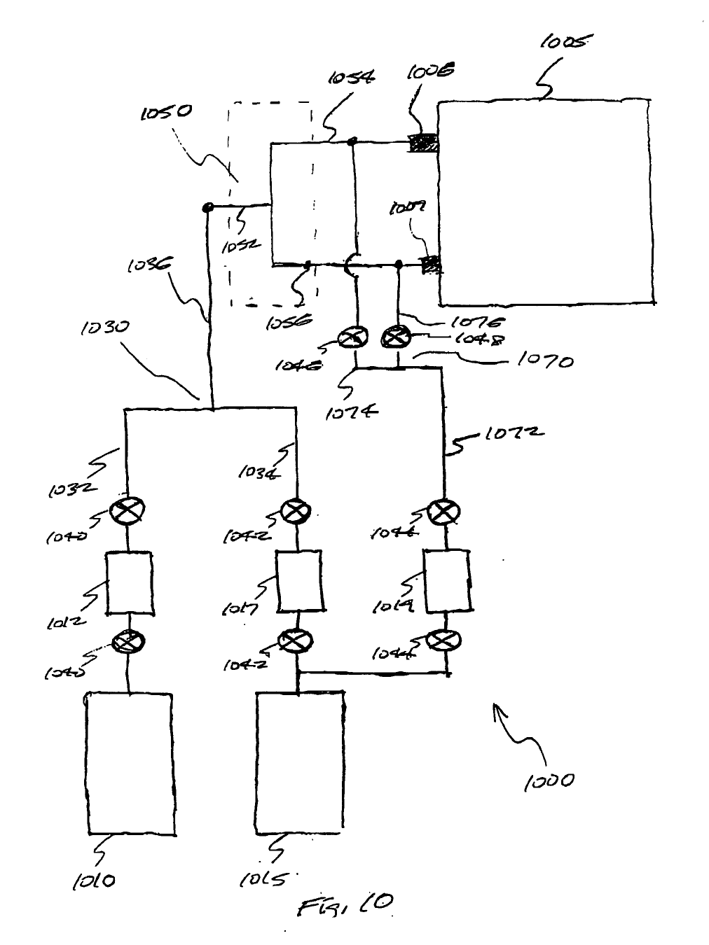

FIG. 10 shows a schematic diagram illustrating one embodiment of a gas delivery system 1000 for controlling the flow of gas to gas interface 1005. Gas interface 1005 may be adapted to flow gas to a variety of process chambers. For example, gas interface 1005 may be substantially similar to gas interface 434 illustrated in FIG. 5, which is structured to provide two gas flow channels into upper portion 418 of process chamber 400. Consequently, during substrate processing, a first gas flow entering a first inlet port 1006 may be directed to flow across a first portion of a substrate contained within a process chamber and a second gas flow entering a second inlet port 1007 may be directed to flow across a second portion of the substrate.

Gas delivery system 1000 may include a first gas source 1010, a second gas source 1015, a first manifold 1030, a second manifold 1050, a third manifold 1070, and gas interface 1005. First manifold 1030 may include a first inlet 1032, a second inlet 1034, and a first outlet 1036. Second manifold 1050 may include a third inlet 1052, a second outlet 1054, and a third outlet 1056. Third manifold 1070 may include a fourth inlet 1072, a fourth outlet 1074, and a fifth outlet 1076. Gas interface 1005 may include first inlet port 1006 and second inlet port 1007.

First inlet 1032 and second inlet 1034 of first manifold 1030 may be coupled to first gas source 1010 and second gas source 1015, respectively. First outlet 1036 of first manifold 1030 may be coupled to third inlet 1052 of second manifold 1050. Second outlet 1054 and third outlet 1056 of second manifold 1050 may be coupled to first inlet port 1006 and second inlet port 1007 of gas interface 1005, respectively. Fourth inlet 1072 of third manifold 1070 may be coupled to second inlet 1034 of first manifold 1030. Fourth outlet 1074 and fifth outlet 1076 of third manifold 1070 may be coupled to second outlet 1054 and third outlet 1056 of second manifold 1050, respectively.

Flow controllers may be structured to gas delivery system 1000 to manipulate the flow of gas through gas delivery system 1000. A first flow controller 1012 may be positioned inline with first inlet 1032 to control the flow rate of gas from first gas source 1010 through first manifold 1030. A second flow controller 1017 may be positioned inline with second inlet 1034 and downstream of fourth inlet 1072 to control the flow rate of gas from second gas source 1015 through first manifold 1030. A third flow controller 1019 may be positioned inline with fourth inlet 1072 to control the flow rate of gas from second gas source 1015 through third manifold 1070.

As described above, first flow controller 1012 and second flow controller 1017 may be adapted to control the flow rate of gases passing through first manifold 1030 and third flow controller 1019 may be adapted to control the flow rate of gases passing through third manifold 1070. In one embodiment, first flow controller 1012, second flow controller 1017 and third flow controller 1019 each may comprise a valve containing a variable orifice which is manually adjusted to control the flow rate of gas passing through the valve body. For example, flow controllers 1012, 1017, and 1019 each may comprise a needle valve which is adjusted to permit or restrict gas flow by the movement of a pointed plug or needle in an orifice or tapered orifice in the valve body. A wide variety of needle valves are commonly available to accommodate various fluid properties and fluid flow rates.

In another embodiment, first flow controller 1012, second flow controller 1017 and third flow controller 1019 each may comprise an automatic flow controller which provides closed loop flow control of gases passing through the automatic flow controller. For example, flow controllers 1012, 1017, and 1019 may each comprise a computer controlled mass flow controller (MFC). An MFC typically comprises an electronic control board, a thermal sensor, and a control valve. During operation, system controller 325 may direct an input signal representing an MFC setpoint to the electronic control board. The input signal received from system controller 325 causes the electronic control board to open the control valve, thereby allowing gas flow through the MFC. A portion of the gas flow through the MFC is directed across the thermal sensor, which generates an output signal proportional to the flow rate of the gas flowing through the MFC. The electronic control board monitors the thermal sensor output signal, compares it to the MFC setpoint, and adjusts the control valve to a setting that provides equalization between the setpoint and the thermal sensor output. Thus, an MFC provides a regulated and highly repeatable flow of gas by means of a closed loop mass flow control system. A wide variety of mass flow controllers are commonly available through manufacturers such as MKS, Horiba, and others to accommodate various fluid properties and fluid flow rates.

In yet another embodiment, first flow controller 1012, second flow controller 1017 and third flow controller 1019 may comprise a combination of manually adjusted flow control valves and automatic flow controllers. For example, first flow controller 1012 and second flow controller 1017 may be structured as mass flow controllers and third flow controller 1019 may be structured as a needle valve. Alternatively, first flow controller 1012 and third flow controller 1019 may be structured as mass flow controllers and second flow controller 1017 may be structured as a needle valve.

Gas delivery system 1000 may further include one or more isolation valves for controlling the flow of gas through portions of gas delivery system 1000. The term “isolation valve” in the following descriptions is generally used to describe a valve which may be configured to either an ON or an OFF condition. An isolation valve configured to an ON position allows for the passage of gas through the valve. Conversely, an isolation valve configured to an OFF position prevents the passage of gas through the valve. An isolation valve may be a computer controlled isolation valve. A computer controlled isolation valve is typically configured to an ON or OFF condition by means of a pneumatic or electrical input signal received from a computer, such as system controller 325. An isolation valve may be either normally closed or normally open. A normally closed isolation valve is configured to an OFF condition in the absence of an input signal. A normally open isolation valve is configured to an ON condition in the absence of an input signal.

Isolation valves 1040, 1042, and 1044 may be arranged inline with first inlet 1032, second inlet 1034, and fourth inlet 1072 immediately upstream and immediately downstream of flow controllers 1012, 1017, and 1019, respectively. Accordingly, isolation valves 1040, 1042, and 1044 may be configured to control the flow of gas from first gas source 1010 and second gas source 1015 to downstream portions of gas delivery system 1000. More specifically, isolation valves 1040, 1042, and 1044 may each be selectively configured to an ON condition to allow for the passage of gas or to an OFF condition to prevent the passage of gas to downstream portions of gas delivery system 1000. Additionally, isolation valves 1046 and 1048 may be arranged inline with fourth outlet 1074 and fifth outlet 1076 of third manifold 1070, respectively. Isolation valves 1046 and 1048 may be selectively configured to control the flow of gas from second gas source 1015 through third manifold 1070 to second outlet 1054 and third outlet 1056 of second manifold 1050, respectively.

During substrate processing, isolation valves 1040 and 1042 may each be configured to an ON condition, thereby allowing gas to flow from first gas source 1010 and second gas source 1015 through first flow controller 1012 and second flow controller 1017, respectively. First flow controller 1012 may be configured to a first flow setpoint and second flow controller 1017 may be configured to a second flow setpoint, thereby controlling the flow rate and composition of gases passing through first manifold 1030 and into second manifold 1050. Gas from first gas source 1010 and second gas source 1015 may be mixed together within first manifold 1030 and subsequently directed to third inlet 1036 of second manifold 1050. The gas mixture comprising gas from first gas source 1010 and second gas source 1015 may then be directed into second outlet 1054 and third outlet 1056 of second manifold 1050.

Isolation valves 1044 may be configured to an ON condition, thereby allowing gas to flow from second gas source 1015 through third flow controller 1019. Third flow controller 1019 may be configured to a third flow setpoint, thereby controlling the flow rate of gas from second gas source 1015 passing through third manifold 1070. Isolation valve 1046 may be configured to an ON condition, thereby allowing gas to flow from second gas source 1015 through fourth gas outlet 1074 into second gas outlet 1054 of second manifold 1050. Similarly, isolation valve 1048 may be configured to an ON condition, thereby allowing gas to flow from second gas source 1015 through fifth gas outlet 1076 into third gas outlet 1056 of second manifold 1050. Gas flows directed into second gas outlet 1054 and third gas outlet 1056 from first manifold 1030 and third manifold 1070 may be subsequently directed into first inlet port 1006 and second inlet port 1007 of gas interface 1005.

Isolation valves 1046, and 1048 may be independently configurable such that one valve may be configured to an ON condition while another valve is configured to an OFF condition, or both valves may be configured to an ON or OFF condition simultaneously. Consequently, the flow of gas from second gas source 1015 through third manifold 1070 may be directed to either second outlet 1054 or third outlet 1056, or to both second and third outlets simultaneously. As a result, third flow controller 1019 may be used to alter the concentration of gas from second gas source 1015 passing through second outlet 1054 or third outlet 1056.

Gas delivery system 1000 allows the composition and flow rate of gases passing through second outlet 1054 to be varied independently of the composition and flow rate of gases passing through third outlet 1056. Conversely, the composition and flow rate of gases passing through third outlet 1056 may be varied independently of the composition and flow rate of gases passing through second outlet 1054. As a result, the composition and flow rate of the gas mixture passing through second outlet 1054 and/or third outlet 1056 may be “tuned” by altering the flow setpoint of third flow controller 1019. Consequently, gas delivery system 1000 may be used to control process gas flows across two different portions of a substrate in a process chamber, thereby providing a means for minimizing mass transport effects across the surface of a substrate during processing.

In one embodiment gas delivery system 1000 may be integrated with a CVD processing system to control the composition and flow rate of a mixture of monosilane (SiH₄) and phosphine (PH₃) across two different portions of a silicon substrate. For example, first gas source 1010 may comprise monosilane and second gas source 1015 may comprise phosphine. During substrate processing, isolation valves 1040 and 1042 may each be configured to an ON condition, thereby allowing monosilane to flow from first gas source 1010 and phosphine to flow from second gas source 1015 through first flow controller 1012 and second flow controller 1017, respectively. First flow controller 1012 may be configured to a first flow setpoint and second flow controller 1017 may be configured to a second flow setpoint, thereby controlling the flow rate and concentration of monosilane and phosphine passing through first manifold 1030 and into second manifold 1050. Monosilane from first gas source 1010 and phosphine from second gas source 1015 may be mixed together within first manifold 1030 and subsequently directed to third inlet 1036 of second manifold 1050. The monosilane and phosphine gas mixture may then be directed into second outlet 1054 and third outlet 1056 of second manifold 1050.

In this embodiment, isolation valves 1044 may be configured to an ON condition, thereby allowing phosphine to flow from second gas source 1015 through third flow controller 1019. Third flow controller 1019 may be configured to a third flow setpoint, thereby controlling the flow rate of phosphine from second gas source 1015 passing through third manifold 1070. Isolation valve 1046 may be configured to an ON condition, thereby allowing phosphine to flow from second gas source 1015 through fourth gas outlet 1074 into second gas outlet 1054 of second manifold 1050. Similarly, isolation valve 1048 may be configured to an ON condition, thereby allowing phosphine to flow from second gas source 1015 through fifth gas outlet 1076 into third gas outlet 1056 of second manifold 1050. Monosilane and phosphine directed into second gas outlet 1054 and third gas outlet 1056 from first manifold 1030 and third manifold 1070 may be subsequently directed into first inlet port 1006 and second inlet port 1007 of gas interface 1005 and across the surface of a substrate.

Isolation valves 1046, and 1048 may be independently configurable such that one valve may be configured to an ON condition while another valve is configured to an OFF condition, or both valves may be configured to an ON or OFF condition simultaneously. Consequently, the flow of phosphine from second gas source 1015 through third manifold 1070 may be directed to either second outlet 1054 or third outlet 1056, or to both second and third outlets simultaneously. As a result, third flow controller 1019 may be used to alter the concentration of phosphine passing through second outlet 1054 or third outlet 1056.

In alternative embodiments, first gas source 1010 may comprise an alternative source of silicon, such as dichlorosilane (SiH₂Cl₂) or trichlorosilane (HSiCl₃) and second gas source 1015 may comprise germane. In other embodiments, gas delivery system 1000 may be integrated with a CVD processing system to control the composition and flow rate of a gas mixture comprising a silicon source and an inert gas across two different portions of a substrate. For example, first gas source 1010 may comprise monosilane, dichlorosilane, or trichlorosilane and second gas source 1015 may comprise hydrogen.

In the above description, gas delivery system 1000 is structured to a gas interface 1005 comprising two inlet ports 1006 and 1007. However, it is to be noted that gas delivery system 1000 may be adapted to flow one or more gases to a variety of gas interfaces corresponding to various process chamber configurations.

For example, in one embodiment gas delivery system 1000 may be adapted to a gas interface such as gas interface 434 in FIG. 6 by dividing second gas outlet 1054 into two conduits coupled to first outside inlet port 610 and second outside inlet port 615, and coupling third gas outlet 1056 to central inlet port 605. Alternatively third gas outlet 1056 may be divided into two conduits which are coupled to first outside inlet port 610 and second outside inlet port 615 and second gas outlet 1054 may be coupled to central inlet port 605. In either configuration, third flow controller 1019 may be used to alter the concentration of gas from second gas source 1015 passing through second gas outlet 1054 and third gas outlet 1056, thereby increasing or decreasing the concentration of gas from second gas source 1015 in the gas flows passing across a central portion and first and second outside portions of a substrate.

In another embodiment, gas delivery system 1000 may be adapted to a gas interface such as gas interface 434 in FIG. 7 by dividing second gas outlet 1054 into three conduits which are coupled to first outside inlet port 720, second outside inlet port 725, and central inlet port 705; and dividing third gas outlet 1056 into two conduits which are coupled to first middle inlet port 710 and second middle inlet port 715. Alternatively, third gas outlet 1056 may be divided into three conduits which are coupled to first outside inlet port 720, second outside inlet port 725, and central inlet port 705; and second gas outlet 1054 may be divided into two conduits which are coupled to first middle inlet port 710 and second middle inlet port 715. In either configuration, third flow controller 1019 may be used to alter the concentration of gas from second gas source 1015 passing through second gas outlet 1054 and third gas outlet 1056, thereby increasing or decreasing the concentration of gas from second gas source 1015 in the gas flows passing across central, first outside, second outside, first middle, and second middle portions of a substrate.

In yet another embodiment, gas delivery system 1000 may be adapted to a gas interface such as gas interface 875 in FIG. 8 by dividing second gas outlet 1054 into two conduits coupled to center inlet port 940 and outer inlet port 950, and coupling third gas outlet 1056 to middle inlet port 945. Alternatively third gas outlet 1056 may be divided into two conduits which are coupled to center inlet port 940 and outer inlet port 950, and second gas outlet 1054 may be coupled to middle inlet port 945. In either configuration, third flow controller 1019 may be used to alter the concentration of gas from second gas source 1015 passing through second gas outlet 1054 and third gas outlet 1056, thereby increasing or decreasing the amount of gas passing across a central portion and middle and outer annular portions of a substrate.

Gas delivery system 1000 may also include a variety of inline filters, purifiers, pressure transducers, and other such devices as are commonly used on substrate processing systems. These types of components have been omitted for illustrative purposes so as to not obscure the description of the present invention.

Gas Delivery System II

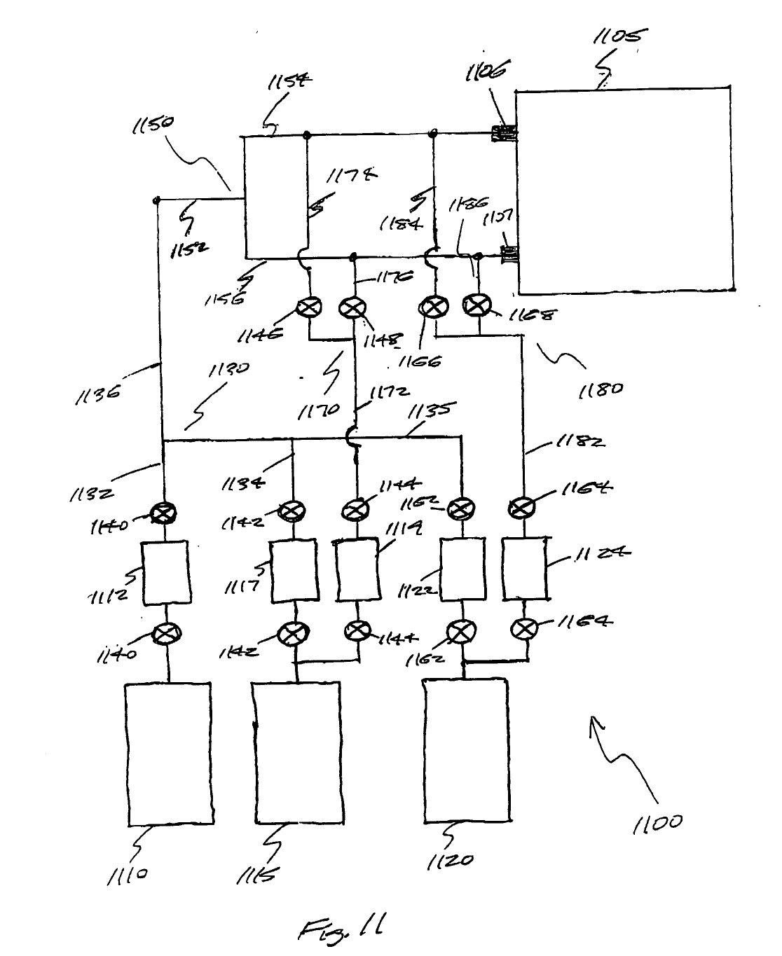

FIG. 11 shows a schematic diagram illustrating a second embodiment of a gas delivery system 1100 for controlling the flow of gas to gas interface 1105. Gas interface 1105 may be adapted to flow gas to a variety of process chambers. For example, gas interface 1105 may be substantially similar to gas interface 434 illustrated in FIG. 5, which is structured to provide two gas flow channels into upper portion 418 of process chamber 400. Consequently, during substrate processing, a first gas flow entering a first inlet port 1106 may be directed to flow across a first portion of a substrate contained within a process chamber, and a second gas flow entering a second inlet port 1107 may be directed to flow across a second portion of the substrate.

Gas delivery system 1100 may include a first gas source 1110, a second gas source 1115, a third gas source 1120, a first manifold 1130, a second manifold 1150, a third manifold 1170, and a fourth manifold 1180. First manifold 1130 may include a first inlet 1132, a second inlet 1134, a third inlet 1135, and a first outlet 1136. Second manifold 1150 may include a fourth inlet 1152, a second outlet 1154, and a third outlet 1156. Third manifold 1170 may include a fifth inlet 1172, a fourth outlet 1174, and a fifth outlet 1176. Fourth manifold 1180 may include a sixth inlet 1182, a sixth outlet 1184, and a seventh outlet 1186. Gas interface 1105 may include first inlet port 1106 and second inlet port 1107.

First inlet 1132, second inlet 1134, and third inlet 1135 of first manifold 1130 may be coupled to first gas source 1110, second gas source 1115, and third gas source 1120, respectively. First outlet 1136 of first manifold 1130 may be coupled to fourth inlet 1152 of second manifold 1150. Second outlet 1154 and third outlet 1156 of second manifold 1150 may be coupled to first inlet port 1106 and second inlet port 1107 of gas interface 1105, respectively. Fifth inlet 1172 of third manifold 1170 may be coupled to second inlet 1134 of first manifold 1130. Fourth outlet 1174 and fifth outlet 1176 of third manifold 1170 may be coupled to second outlet 1154 and third outlet 1156 of second manifold 1150, respectively. Sixth inlet 1182 of fourth manifold 1180 may be coupled to third inlet 1135 of first manifold 1130. Sixth outlet 1184 and seventh outlet 1186 of fourth manifold 1180 may be coupled to second outlet 1154 and third outlet 1156 of second manifold 1150, respectively.

FIG. 11 shows sixth outlet 1184 of fourth manifold 1180 as being coupled to second outlet 1154 of second manifold 1150 downstream of the point at which fourth outlet 1174 of third manifold 1170 is coupled to second outlet 1154 of second manifold 1150. Similarly, FIG. 11 shows seventh outlet 1186 of fourth manifold 1180 as being coupled to second outlet 1156 of second manifold 1150 downstream of the point at which fifth outlet 1176 of third manifold 1170 is coupled to third outlet 1156 of second manifold 1150. In alternative embodiments, sixth outlet 1184 of fourth manifold 1180 may be coupled to second outlet 1154 of second manifold 1150 upstream of the point at which fourth outlet 1174 of third manifold 1170 is coupled to second outlet 1154 of second manifold 1150. Similarly, seventh outlet 1186 of fourth manifold 1180 may be coupled to second outlet 1154 of second manifold 1150 upstream of the point at which fifth outlet 1176 of third manifold 1170 is coupled to third outlet 1156 of second manifold 1150.

Flow controllers may be structured to gas delivery system 1100 to manipulate the flow of gas through gas delivery system 1100. A first flow controller 1112 may be positioned inline with first inlet 1132 to control the flow rate of gas from first gas source 1140 through first manifold 1130. A second flow controller 1115 may be positioned inline with second inlet 1134 and downstream of fifth inlet 1172 to control the flow rate of gas from second gas source 1115 through first manifold 1130. A third flow controller may be positioned inline with third inlet 1135 to control the flow rate of gas from third gas source 1120 through first manifold 1130. A fourth flow controller 1119 may be positioned inline with fifth inlet 1172 to control the flow rate of gas from second gas source 1115 through third manifold 1170. A fifth flow controller 1124 may be positioned inline with sixth inlet 1182 to control the flow rate of gas from third gas source 1120 through fourth manifold 1180.

In one embodiment, first flow controller 1112, second flow controller 1117, third flow controller 1122, fourth flow controller 1119, and fifth flow controller 1124 each may comprise a valve containing a variable orifice which is manually adjusted to control the flow rate of gas passing through the valve body. For example, flow controllers 1112, 1117, 1122, 1119, and 1124 each may comprise a needle valve which is adjusted to permit or restrict gas flow. In another embodiment, flow controllers 1112, 1117, 1122, 1119, and 1124 each may comprise an automatic flow controller, such as a computer controlled mass flow controller, which provides closed loop flow control. In yet another embodiment, flow controllers 1112, 1117, 1122, 1119, and 1124 may comprise a combination of manually adjusted flow control valves and automatic flow controllers. For example, first flow controller 1112, second flow controller 1117, and third flow controller 1122 may be structured as mass flow controllers; and fourth flow controller 1119 and fifth flow controller 1124 may be structured as needle valves. Alternatively, first flow controller 1112, fourth flow controller 1119, and fifth flow controller 1124 may be structured as mass flow controllers; and second flow controller 1117 and third flow controller 1122 may be structured as a needle valves.

Gas delivery system 1100 may further include one or more isolation valves for controlling the flow of gas through portions of gas delivery system 1100. Isolation valves 1140, 1142, and 1162 may be arranged inline with first inlet 1132, second inlet 1134, and third inlet 1135 of first manifold 1130 immediately upstream and immediately downstream of flow controllers 1112, 1117, and 1122, respectively. Additionally, isolation valves 1144 and 1164 may be arranged inline with fourth inlet 1172 of third manifold 1170 and fifth inlet 1182 of fourth manifold 1180 immediately upstream and immediately downstream of flow controllers 1119, and 1124, respectively. Accordingly, isolation valves 1140, 1142, 1144, 1162, and 1164 may be configured to control the flow of gas from first gas source 1110, second gas source 1115, and third gas source 1120 to downstream portions of gas delivery system 1100. More specifically, isolation valves 1140, 1142, 1144, 1162, and 1164 may each be selectively configured to an ON condition to allow for the passage of gas or to an OFF condition to prevent the passage of gas to downstream portions of gas delivery system 1100.

Isolation valves 1146 and 1148 may be arranged inline with fourth outlet 1174 and fifth outlet 1176 of third manifold 1170, respectively. Isolation valves 1146 and 1148 may be selectively configured to control the flow of gas from second gas source 1115 through third manifold 1170 to second outlet 1154 and third outlet 1156 of second manifold 1150. Isolation valves 1166 and 1168 may be arranged inline with sixth outlet 1184 and seventh outlet 1186 of fourth manifold 1180, respectively. Isolation valves 1166 and 1168 may be selectively configured to control the flow of gas from third gas source 1120 through fourth manifold 1180 to second outlet 1154 and third outlet 1156 of second manifold 1150.

During substrate processing, isolation valves 1140, 1142, and 1162 may each be configured to an ON condition, thereby allowing gas to flow from first gas source 1110, second gas source 1115, and third gas source 1120 through first flow controller 1112, second flow controller 1117, and third flow controller 1122, respectively. First flow controller 1112 may be configured to a first flow setpoint, second flow controller 1117 may be configured to a second flow setpoint, and third flow controller 1122 may be configured to a third flow setpoint, thereby controlling the flow rate and composition of gases passing through first manifold 1130 and into second manifold 1150. Gases from first gas source 1110, second gas source 1115, and third gas source 1120 may mix together within first manifold 1130 and subsequently enter fourth inlet 1152 of second manifold 1150. The gas mixture comprising gas from first gas source 1110, second gas source 1115, and third gas source 1120 may then flow into second outlet 1154 and third outlet 1156 of second manifold 1150.

Isolation valves 1144 may be configured to an ON condition, thereby allowing gas to flow from second gas source 1115 through fourth flow controller 1119. Fourth flow controller 1119 may be configured to a fourth flow setpoint, thereby controlling the flow rate of gas from second gas source 1115 passing through third manifold 1170. Isolation valve 1146 may be configured to an ON condition, thereby allowing gas to flow from second gas source 1115 through fourth gas outlet 1174 into second gas outlet 1154 of second manifold 1150. Similarly, isolation valve 1148 may be configured to an ON condition, thereby allowing gas to flow from second gas source 1115 through fifth gas outlet 1176 into third gas outlet 1156 of second manifold 1150. Isolation valves 1146 and 1148 may be independently configurable such that one valve may be configured to an ON condition while the other valve is configured to an OFF condition, or both isolation valves may be configured to an ON or OFF condition simultaneously. Consequently, the flow of gas from second gas source 1115 through third manifold 1170 may be directed to either second outlet 1154 or third outlet 1156, or to both second and third outlets simultaneously.

As above, isolation valves 1166 and 1168 may be configured to an ON condition, thereby allowing gas to flow from third gas source 1120 through fifth flow controller 1124. Fifth flow controller 1124 may be configured to a fifth flow setpoint, thereby controlling the flow rate of gas from third gas source 1120 passing through fourth manifold 1180. Isolation valve 1166 may be configured to an ON condition, thereby allowing gas flow from third gas source 1120 through sixth gas outlet 1184 into second gas outlet 1154 of second manifold 1150. Similarly, isolation valve 1168 may be configured to an ON condition, thereby allowing gas flow from third gas source 1120 through seventh gas outlet 1186 into third gas outlet 1156 of second manifold 1150. Isolation valves 1166 and 1168 may be independently configurable such that one valve may be configured to an ON condition while the other valve is configured to an OFF condition, or both isolation valves may be configured to an ON or OFF condition simultaneously. Consequently, the flow of gas from third gas source 1120 through fourth manifold 1180 may be directed to either second outlet 1154 or third outlet 1156, or to both second and third outlets simultaneously. Gas flows directed into second gas outlet 1154 and third gas outlet 1156 from first manifold 1130, third manifold 1170, and fourth manifold 1180 are subsequently directed into first inlet port 1106 and second inlet port 1107 of gas interface 1105.

The flow of gas from second gas source 1115 through third manifold 1170 and/or the flow of gas from third gas source 1120 through fourth manifold 1180 may be directed to either second outlet 1154 or third outlet 1156, or to both second and third outlets simultaneously. Hence, the composition and flow rate of gases passing through second outlet 1154 may be varied independently of the composition and flow rate of gases passing through third outlet 1156, and the composition and flow rate of gases passing through third outlet 1156 may be varied independently of the composition and flow rate of gases passing through second outlet 1154. As a result, the composition and flow rate of the gas mixture passing through second outlet 1154 and/or third outlet 1156 may be “tuned” by altering the flow setpoint of fourth flow controller 1119 and fifth flow controller 1124. Consequently, gas delivery system 1100 may be used to control process gas flows across two different portions of a substrate in a process chamber, thereby providing a means for minimizing mass transport effects across the surface of a substrate during processing.

In one embodiment, gas delivery system 1100 may be integrated with a CVD processing system to control the composition and flow rate of a mixture of monosilane (SiH₄), germane (GeH₄), and diborane (B₂H₆) across two different portions of a silicon wafer. For example, first gas source 1110 may comprise monosilane, second gas source 1115 may comprise germane, and third gas source 1120 may comprise diborane. These gases may also be diluted by an inert carrier gas, such as hydrogen (H₂). During substrate processing, isolation valves 1140, 1142, and 1162 may each be configured to an ON condition, thereby allowing monosilane to flow from first gas source 1110, germane to flow from second gas source 1115, and diborane to flow from third gas source 1120 through first flow controller 1112, second flow controller 1117, and third flow controller 1122, respectively. First flow controller 1112 may be configured to a first flow setpoint, second flow controller 1117 may be configured to a second flow setpoint, and third flow controller 1122 may be configured to a third flow setpoint, thereby controlling the flow rate and composition of monosilane, germane, and diborane passing through first manifold 1130 and into second manifold 1150. Monosilane from first gas source 1110, germane from second gas source 1115, and diborane from third gas source 1120 may mix together within first manifold 1130 and subsequently enter fourth inlet 1152 of second manifold 1150. The gas mixture comprising monosilane, germane, and diborane may then flow into second outlet 1154 and third outlet 1156 of second manifold 1150.

Isolation valves 1144 may be configured to an ON condition, thereby allowing germane to flow from second gas source 1115 through fourth flow controller 1119. Fourth flow controller 1119 may be configured to a fourth flow setpoint, thereby controlling the flow rate of germane from second gas source 1115 passing through third manifold 1170. Isolation valve 1146 may be configured to an ON condition, thereby allowing germane to flow from second gas source 1115 through fourth gas outlet 1174 into second gas outlet 1154 of second manifold 1150. Similarly, isolation valve 1148 may be configured to an ON condition, thereby allowing germane to flow from second gas source 1115 through fifth gas outlet 1176 into third gas outlet 1156 of second manifold 1150. Isolation valves 1146 and 1148 may be independently configurable such that one valve may be configured to an ON condition while the other valve is configured to an OFF condition, or both isolation valves may be configured to an ON or OFF condition simultaneously. Consequently, the flow of germane from second gas source 1115 through third manifold 1170 may be directed to either second outlet 1154 or third outlet 1156, or to both second and third outlets simultaneously. As a result, fourth flow controller 1119 may be used to alter the concentration of germane passing through second outlet 1154 and/or third outlet 1156.

Similarly, isolation valves 1164 may be configured to an ON condition, thereby allowing diborane to flow from third gas source 1120 through fifth flow controller 1124. Fifth flow controller 1124 may be configured to a fifth flow setpoint, thereby controlling the flow rate of diborane from third gas source 1120 passing through fourth manifold 1180. Isolation valve 1166 may be configured to an ON condition, thereby allowing diborane to flow from third gas source 1120 through sixth gas outlet 1184 into second gas outlet 1154 of second manifold 1150. Similarly, isolation valve 1168 may be configured to an ON condition, thereby allowing diborane to flow from third gas source 1120 through seventh gas outlet 1186 into third gas outlet 1156 of second manifold 1150. Isolation valves 1166 and 1168 may be independently configurable such that one valve may be configured to an ON condition while the other valve is configured to an OFF condition, or both isolation valves may be configured to an ON or OFF condition simultaneously. Consequently, the flow of diborane from third gas source 1120 through fourth manifold 1180 may be directed to either second outlet 1154 or third outlet 1156, or to both second and third outlets simultaneously. As a result, fifth flow controller 1124 may be used to alter the concentration of diborane passing through second outlet 1154 and/or third outlet 1156.

The flow of monosilane, germane, and diborane directed into second gas outlet 1154 and third gas outlet 1156 from first manifold 1130, third manifold 1170, and fourth manifold 1180 may be subsequently directed into first inlet port 1106 and second inlet port 1107 of gas interface 1105 and across the surface of a substrate. In alternative embodiments, first gas source 1110 may comprise an alternative source of silicon, such as dichlorosilane (SiH₂Cl₂) or trichlorosilane (HSiCl₃), second gas source 1115 may comprise germane, and third gas source 1120 may comprise diborane.

In the above description, gas delivery system 1100 is structured to a gas interface 1105 comprising two inlet ports 1106 and 1107. However, it is to be noted that gas delivery system 1100 may be adapted to flow one or more gases to a variety of gas interfaces corresponding to various process chamber configurations.

For example, in one embodiment gas delivery system 1100 may be adapted to a gas interface such as gas interface 434 in FIG. 6 by dividing second gas outlet 1154 into two conduits coupled to first outside inlet port 610 and second outside inlet port 615, and coupling third gas outlet 1156 to central inlet port 605. Alternatively third gas outlet 1156 may be divided into two conduits which are coupled to first outside inlet port 610 and second outside inlet port 615, and second gas outlet 1154 may be coupled to central inlet port 605. In either configuration, fourth flow controller 1119 may be used to alter the concentration of gas from second gas source 1115 passing through second gas outlet 1154 and third gas outlet 1156, thereby increasing or decreasing the concentration of gas from second gas source 1115 in the gas flows passing across a central portion and first and second outside portions of a substrate. Similarly, fifth flow controller 1124 may be used to alter the concentration of gas from third gas source 1120 passing through second gas outlet 1154 and third gas outlet 1156, thereby increasing or decreasing the concentration of gas from third gas source 1120 in the gas flows passing across a central portion and first and second outside portions of a substrate.

In another embodiment, gas delivery system 1100 may be adapted to a gas interface such as gas interface 434 in FIG. 7 by dividing second gas outlet 1154 into three conduits which are coupled to first outside inlet port 720, second outside inlet port 725, and central inlet port 705; and dividing third gas outlet 1156 into two conduits which are coupled to first middle inlet port 710 and second middle inlet port 715. Alternatively, third gas outlet 1156 may be divided into three conduits which are coupled to first outside inlet port 720, second outside inlet port 725, and central inlet port 705; and second gas outlet 1154 may be divided into two conduits which are coupled to first middle inlet port 710 and second middle inlet port 715. In either configuration, fourth flow controller 1119 may be used to alter the concentration of gas from second gas source 1115 passing through second gas outlet 1154 and third gas outlet 1156, thereby increasing or decreasing the concentration of gas from second gas source 1115 in the gas flows passing across central, first outside, second outside, first middle, and second middle portions of a substrate. Similarly, fifth flow controller 1124 may be used to alter the concentration of gas from third gas source 1120 passing through second gas outlet 1154 and third gas outlet 1156, thereby increasing or decreasing the concentration of gas from second gas source 1115 in the gas flows passing across central, first outside, second outside, first middle, and second middle portions of a substrate.

In yet another embodiment, gas delivery system 1100 may be adapted to a gas interface such as gas interface 875 in FIG. 8 by dividing second gas outlet 1154 into two conduits coupled to center inlet port 940 and outer inlet port 950, and coupling third gas outlet 1156 to middle inlet port 945. Alternatively third gas outlet 1156 may be divided into two conduits which are coupled to center inlet port 940 and outer inlet port 950, and second gas outlet 1154 may be coupled to middle inlet port 945. In either configuration, fourth flow controller 1119 may be used to alter the concentration of gas from second gas source 1115 passing through second gas outlet 1054 and third gas outlet 1056, thereby increasing or decreasing the concentration of gas from gas source 1115 passing across a central portion and middle and outer annular portions of a substrate. Similarly, fifth flow controller 1124 may be used to alter the concentration of gas from third gas source 1120 passing through second gas outlet 1154 and third gas outlet 1156, thereby increasing or decreasing the concentration of gas from third gas source 1120 passing across a central portion and middle and outer annular portions of a substrate.

Gas delivery system 1100 may also include a variety of inline filters, purifiers, pressure transducers, and other such devices as are commonly used on substrate processing systems. These types of components have been omitted for illustrative purposes so as to not obscure the description of the present invention.

Gas Delivery System III

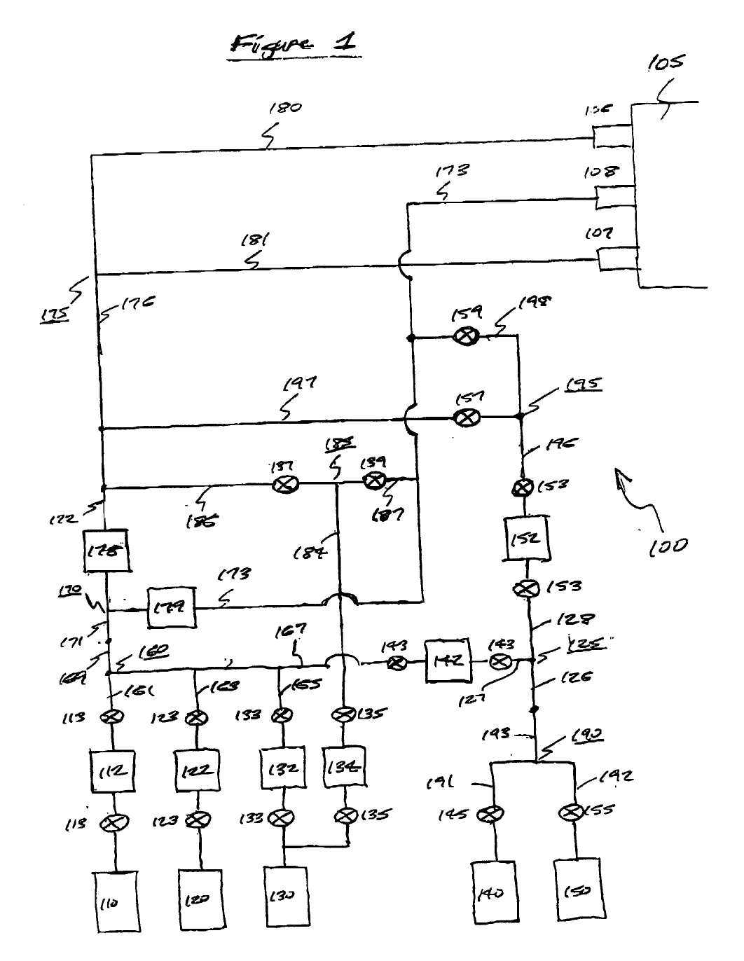

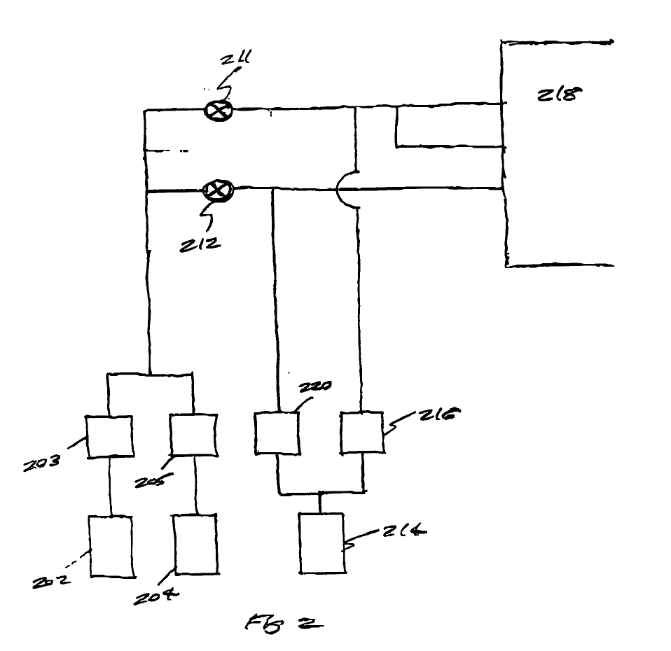

FIG. 1 shows a schematic diagram illustrating a preferred embodiment of a gas delivery system 100 for controlling the flow of gas to gas interface 105. Gas interface 105 may be adapted to flow gas to a variety of process chambers. For example, gas interface 105 may be substantially similar to gas interface 434 illustrated in FIG. 6, which is structured to provide three gas flow channels into upper portion 418 of process chamber 400. Consequently, during substrate processing, a first gas flow entering a first inlet port 106 may be directed to flow across a first outside portion of a substrate contained within a process chamber, a second gas flow entering a second inlet port 107 may be directed to flow across a second outside portion of the substrate, and a third gas flow entering a third inlet port 108 may be directed to flow across a central portion of the substrate.

Gas delivery system 100 may include a first gas source 110, a second gas source 120, a third gas source 130, a fourth gas source 140, a fifth gas source 150, a first manifold 160, a second manifold 170, a third manifold 175, a fourth manifold 185, a fifth manifold 190, a sixth manifold 125, and a seventh manifold 195. First manifold 160 may include a first inlet 161, a second inlet 163, a third inlet 165, a fourth inlet 167, and a first outlet 169. Second manifold 170 may include a fifth inlet 171, a second outlet 172, and a third outlet 173. Third manifold 175 may include a sixth inlet 176, a fourth outlet 180, and a fifth outlet 181. Fourth manifold 185 may include a seventh inlet 184, a sixth outlet 186, and a seventh outlet 187. Fifth manifold 190 may include an eighth inlet 191, a ninth inlet 192, and an eighth outlet 193. Sixth manifold 125 may include a tenth inlet 126, a ninth outlet 127, and a tenth outlet 128. Seventh manifold 195 may include an eleventh inlet 196, an eleventh outlet 197, and a twelfth outlet 198. Gas interface 105 may include first inlet port 106, second inlet port 108, and third inlet port 107.

First inlet 161, second inlet 163, third inlet 165, and fourth inlet 167 of first manifold 160 may be coupled to first gas source 110, second gas source 120, third gas source 130, and ninth outlet 127 of sixth manifold 125, respectively. First outlet 169 of first manifold 160 may be coupled to fifth inlet 171 of second manifold 170. Second outlet 172 of second manifold 170 may be coupled to sixth inlet 176 of third manifold 175; third outlet 173 of second manifold 170 may be coupled to third inlet port 108. Fourth outlet 180 and fifth outlet 181 of third manifold 175 may be coupled to first inlet port 106 and second inlet port 107, respectively.

Seventh inlet 184 of fourth manifold 185 may be coupled to third inlet 165 of first manifold 160. Sixth outlet 186 of fourth manifold 185 may be coupled to second outlet 172 of second manifold 170. Similarly, seventh outlet 187 of fourth manifold 185 may be coupled to third outlet 173 of second manifold 170. Eighth inlet 191 and ninth inlet 192 of fifth manifold 190 may be coupled to fourth gas source 140 and fifth gas source 150, respectively. Eighth outlet 193 of fifth manifold 190 may be coupled to tenth inlet 126 of sixth manifold 125. Ninth outlet 127 of sixth manifold 125 may be coupled to fourth inlet 167 of first manifold 160. Tenth outlet 128 of sixth manifold 125 may be coupled to eleventh inlet 196 of seventh manifold 195. Eleventh outlet 197 of seventh manifold 195 may be coupled to second outlet 172 of second manifold 170. Twelfth outlet 198 of seventh manifold 195 may be coupled to third outlet 173 of second manifold 170.

Gas delivery system 100 may further include flow controllers to manipulate the flow of gas through gas delivery system 100. A first flow controller 112 may be positioned inline with first inlet 161 to control the flow rate of gas from first gas source 110 through first manifold 160. A second flow controller 122 may be positioned inline with second inlet 163 to control the flow rate of gas from second gas source 120 through first manifold 160. A third flow controller 132 may be positioned inline with third inlet 165 to control the flow rate of gas from third gas source 130 through first manifold 160; a fourth flow controller 134 may be positioned inline with seventh inlet 184 to control the flow rate of gas from third gas source 130 through fourth manifold 185. A fifth flow controller 142 may be positioned inline with fourth inlet 167 to control the flow rate of gas from fourth gas source 140 and/or fifth gas source 150 through first manifold 160. A sixth flow controller 152 may be positioned inline with eleventh inlet 196 to control the flow rate of gas from fourth gas source 140 and/or fifth gas source 150 through seventh manifold 195. Flow controllers 112, 122, 132, 134, 142, and 152 are preferably computer controlled mass flow controllers, such as Series 8100 and Series 1660 mass flow controllers manufactured by the UNIT Corporation.

Gas delivery system 100 may further include a plurality of isolation valves for controlling the flow of gas through portions of gas delivery system 100. Isolation valves 113, 123, 133, and 143 may be arranged inline with first inlet 161, second inlet 163, third inlet 165, and fourth inlet 167 of first manifold 160 immediately upstream and immediately downstream of flow controllers 112, 122, 132, and 142, respectively. Isolation valves 135 may be may be arranged inline with seventh inlet 184 of fourth manifold 185 immediately upstream and immediately downstream of flow controller 134; isolation valves 137 and 139 may be arranged inline with sixth outlet 186 and seventh outlet 187 of fourth manifold 185, respectively. Isolation valve 137 may be configured to control the flow of gas from third gas source 130 through sixth outlet 186 of fourth manifold 185 to second outlet 172 of second manifold 170. Similarly, isolation valve 139 may be configured to control the flow of gas from third gas source 130 through seventh outlet 187 of fourth manifold 185 to third outlet 173 of second manifold 170.

Isolation valves 145 and 155 may be arranged inline with eighth inlet 191 and ninth inlet 192 of fifth manifold 190. Isolation valves 153 may be arranged inline with eleventh inlet 196 immediately upstream and immediately downstream of flow controller 152; isolation valves 157 and 159 may be arranged inline with eleventh outlet 197 and twelfth outlet 198 of seventh manifold 195, respectively. Isolation valve 157 may be configured to control the flow of gas from fourth gas source 140 and/or fifth gas source 150 through seventh manifold 195 to sixth inlet 176 of third manifold 175. Similarly, isolation valve 159 may be configured to control the flow of gas from fourth gas source 140 and/or fifth gas source 150 through seventh manifold 195 to third outlet 173 of second manifold 170.

Isolation valves 113, 123, 133, 135, 143, 137, 139, 145, 155, 153, 157, and 159 are preferably Veriflo Series 944, 945, and 955 pneumatic diaphragm valves manufactured by the Parker Hannifin Corporation. Additionally, isolation valves 113, 123, 133, 135, 143, 137, 139, 145, 155, 153, 157, and 159 are preferably computer controlled isolation valves controlled, for example, by system controller 325.

During substrate processing, isolation valves 113, 123, 133 may each be configured to an ON condition, thereby allowing gas to flow from first gas source 110, second gas source 120, and third gas source 130 through first flow controller 112, second flow controller 122, and third flow controller 132, respectively. Additionally, isolation valves 143, 145 and/or 155 may be configured to an ON condition, thereby allowing gas to flow from fourth gas source 140 and/or fifth gas source 150 through fifth flow controller 142. First flow controller 112 may be configured to a first flow setpoint, second flow controller 122 may be configured to a second flow setpoint, third flow controller 132 may be configured to a third flow setpoint, and fifth flow controller 142 may be configured to a fifth flow setpoint, thereby controlling the flow rate and composition of gases passing through first manifold 160 and into second manifold 170. Gases from first gas source 110, second gas source 120, third gas source 130, fourth gas source 140, and/or fifth gas source 150 may mix together within first manifold 160 and subsequently enter fifth inlet 171 of second manifold 170. The gas mixture comprising gas from first gas source 110, second gas source 120, third gas source 130, fourth gas source 140, and/or fifth gas source 150 may then flow into second outlet 172 and third outlet 173 of second manifold 170. From second outlet 172 of second manifold 170, the gas mixture may flow into sixth inlet 176 of third manifold 175. From sixth inlet 176, the gas mixture may flow through fourth outlet 180 and fifth outlet 181 of third manifold 175 into first inlet port 106 and second inlet port 107, respectively.

Isolation valves 135 may be configured to an ON condition, thereby allowing gas to flow from third gas source 130 through fourth flow controller 134. Fourth flow controller 134 may be configured to a fourth flow setpoint, thereby controlling the flow rate of gas from third gas source 130 passing through fourth manifold 185. Isolation valve 137 may be configured to an ON condition, thereby allowing gas to flow from third gas source 130 through sixth outlet 186. Isolation valve 137 may be configured to an ON condition, thereby allowing gas to flow from third gas source 130 through sixth outlet 186 of fourth manifold 185 into second outlet 172 of second manifold 170. Similarly, isolation valve 139 may be configured to an ON condition, thereby allowing gas to flow from third gas source 130 through seventh gas outlet 187 into third outlet 173 of second manifold 170. Isolation valves 137 and 139 may be independently configurable such that one valve may be configured to an ON condition while the other valve is configured to an OFF condition, or both isolation valves may be configured to an ON or OFF condition simultaneously. Consequently, the flow of gas from third gas source 130 through fourth manifold 185 may be directed separately to second outlet 172 or to third outlet 173. Alternatively the flow of gas from third gas source 130 through fourth manifold 185 may be directed to second outlet 172 and to third outlet 173 simultaneously.

Isolation valves 153, 145 and/or 155 may be configured to an ON condition, thereby allowing gas to flow from fourth gas source 140 and/or fifth gas source 150 through sixth flow controller 152. Sixth flow controller 152 may be configured to a sixth flow setpoint, thereby controlling the flow rate and composition of gases passing through seventh manifold 195. Isolation valve 157 may be configured to an ON condition, thereby allowing gas to flow from fourth gas source 140 and/or fifth gas source 150 through eleventh outlet 197 of seventh manifold 195 into sixth inlet 176 of third manifold 175. Similarly, isolation valve 159 may be configured to an ON condition, thereby allowing gas to flow from fourth gas source 140 and/or fifth gas source 150 through twelfth outlet 198 of seventh manifold 195 into third outlet 173 of second manifold 170. Isolation valves 157 and 159 may be independently configurable such that one valve may be configured to an ON condition while the other valve is configured to an OFF condition, or both isolation valves may be configured to an ON or OFF condition simultaneously. Consequently, the flow of gas from fourth gas source 140 and/or fifth gas source 150 through seventh manifold 195 may be directed separately to sixth inlet 176 or to third outlet 173. Alternatively the flow of gas from third gas source 130 through fourth manifold 185 may be directed to sixth inlet 176 and to third outlet 173 simultaneously.

Gas delivery system 100 may further include a first metering valve 178 and a second metering valve 179 positioned inline with second outlet 172 and third outlet 173 of second manifold 170. Metering valves 178 and 179 may be used to proportion the flow of gases passing through second manifold 170 between second outlet 172 and third outlet 173. For example, first metering valve 178 may be adjusted to have a greater flow restriction than second metering valve 179 such that a greater proportion of gases from fifth inlet 171 will be diverted into third outlet 173 than second outlet 172. Alternatively, second metering valve 179 may be adjusted to have a greater flow restriction than first metering valve 178 such that a greater proportion of gases from fifth inlet 171 will be diverted into second outlet 172 than third outlet 173. In a preferred embodiment, metering valves 178 and 179 are computer controlled flowPoint valves manufactured by Applied Precision of Issaquah, Wash., such as flowpoint valve part number 53-710150-000. Metering valves 178 and 179 may be controlled, for example, by an input signal generated by system controller 325.

As discussed above, the flow of gas from third gas source 130 through fourth manifold 185 may be directed to fourth and fifth outlets 180 and 181 or to third outlet 173. Hence, the composition and flow rate of the gas mixture passing through fourth and fifth outlets 180 and 181 or third outlet 173 may be altered by varying the flow setpoint of fourth flow controller 134. Similarly, the flow of gas from fourth gas source 140 and/or fifth gas source 150 may be directed to fourth and fifth outlets 180 and 181 or third outlet 173. Hence, the composition and flow rate of the gas mixture passing through fourth and fifth outlets 180 and 181 or third outlet 173 may also be altered by varying the flow setpoint of sixth flow controller 152. As shown in FIG. 1, fourth outlet 180, fifth outlet 181, and third outlet 173 may be connected to first inlet port 106, second inlet port 107, and third inlet port 108, respectively. As a result, the composition and flow rate of the gas mixture passing through first inlet port 106, second inlet port 107, and third inlet port 108 may be “tuned” by altering the flow setpoint of fourth flow controller 134 and sixth flow controller 152. Consequently, gas delivery system 100 may be used to control process gas flows across three different portions of a substrate in a process chamber.

In one embodiment, gas delivery system 100 may be integrated with a CVD processing system to control the composition and flow rate of a mixture of hydrogen (H₂), dichlorosilane (SiH₂Cl₂), and a 10% mixture of germane (GeH₄) in hydrogen across three different portions of a silicon wafer in order to deposit a layer of epitaxial SiGe onto the surface of a substrate. For example, first gas source 110 may comprise hydrogen, second gas source 120 may comprise dichlorosilane, and third gas source 130 may comprise a 10% mixture of germane in hydrogen. During substrate processing, isolation valves 113, 123, 133 may each be configured to an ON condition, thereby allowing hydrogen to flow from first gas source 110, dichlorosilane to flow from second gas source 120, and a mixture of germane and hydrogen to flow from third gas source 130 through first flow controller 112, second flow controller 122, and third flow controller 132, respectively. Additionally, isolation valves 143, 145 and/or 155 may be configured to an ON condition, thereby allowing gas to flow from fourth gas source 140 and/or fifth gas source 150 through fifth flow controller 142. First flow controller 112 may be configured to a first flow setpoint, second flow controller 122 may be configured to a second flow setpoint, third flow controller 132 may be configured to a third flow setpoint, and fifth flow controller 142 may be configured to a fifth flow setpoint, thereby controlling the flow rate and composition of gases passing through first manifold 160 and into second manifold 170. Hydrogen from first gas source 110, dichlorosilane from second gas source 120, germane and hydrogen from third gas source 130, and gases from fourth gas source 140 and/or fifth gas source 150 may mix together within first manifold 160 and subsequently enter fifth inlet 171. The gas mixture may then flow into second outlet 172 and third outlet 173. From second outlet 172, the gas mixture may flow through sixth inlet 176, fourth outlet 180, and fifth outlet 181 into first inlet port 106 and second inlet port 107.

In this embodiment, isolation valves 135 may be configured to an ON condition, thereby allowing germane and hydrogen from third gas source 130 to flow through fourth flow controller 134. Fourth flow controller 134 may be configured to a fourth flow setpoint, thereby controlling the flow rate of germane and hydrogen from third gas source 130 passing through fourth manifold 185. Isolation valve 137 may be configured to an ON condition, thereby allowing germane and hydrogen to pass through sixth outlet 186. Isolation valve 137 may be configured to an ON condition, thereby allowing germane and hydrogen to pass through sixth outlet 186 into second outlet 172. Similarly, isolation valve 139 may be configured to an ON condition, thereby allowing germane and hydrogen to pass through seventh gas outlet 187 into third outlet 173. Isolation valves 137 and 139 may be independently configurable such that one valve may be configured to an ON condition while the other valve is configured to an OFF condition, or both isolation valves may be configured to an ON or OFF condition simultaneously. Consequently, the flow germane and hydrogen through fourth manifold 185 may be directed separately to second outlet 172 or to third outlet 173. Alternatively the flow of germane and hydrogen through fourth manifold 185 may be directed to second outlet 172 and to third outlet 173 simultaneously.

In this embodiment, first metering valve 178 and second metering valve 179 may be used to proportion the flow of gases passing through second manifold 170 between second outlet 172 and third outlet 173. For example, first metering valve 178 may be adjusted to have a greater flow restriction than second metering valve 179 such that a greater proportion of gases from fifth inlet 171 will be diverted into third outlet 173 than second outlet 172. Alternatively, second metering valve 179 may be adjusted to have a greater flow restriction than first metering valve 178 such that a greater proportion of gases from fifth inlet 171 will be diverted into second outlet 172 than third outlet 173.

As discussed above, the flow of germane and hydrogen from third gas source 130 through fourth manifold 185 may be directed to fourth and fifth outlets 180 and 181 or to third outlet 173. Hence, the concentration of germane and hydrogen passing through fourth and fifth outlets 180 and 181 or third outlet 173 may be altered by varying the flow setpoint of fourth flow controller 134. As shown in FIG. 1, fourth outlet 180, fifth outlet 181, and third outlet 173 may be connected to first inlet port 106, second inlet port 107, and third inlet port 108, respectively. As a result, the concentration of germane and hydrogen passing through first inlet port 106, second inlet port 107, and third inlet port 108 may be “tuned” by altering the flow setpoint of fourth flow controller 134. Consequently, gas delivery system 100 may be used to control process gas flows across three different portions of a substrate in a process chamber.

In the above description, gas delivery system 100 is structured to a gas interface 105 comprising three inlet ports 106, 107, and 108. However, it is to be noted that gas delivery system 1100 may be adapted to flow one or more gases to a variety of gas interfaces corresponding to various process chamber configurations.

For example, in one embodiment gas delivery system 100 may be adapted to a gas interface such as gas interface 434 in FIG. 7 by coupling third outlet 173 to central inlet port 705; dividing fourth outlet 180 into two conduits which are coupled to first outside inlet port 720 and second outside inlet port 725; and dividing fifth outlet 181 into two conduits which are coupled to first middle inlet port 710 and second middle inlet port 715. In this embodiment, fourth flow controller 134 may be used to alter the concentration of gas from third gas source 130 passing through third outlet 173, thereby increasing or decreasing the concentration of gas from third gas source 130 in the gas flow passing across a central portion of a substrate. Similarly, fourth flow controller 134 may also be used to alter the concentration of gas from third gas source 130 passing through fourth outlet 180 and fifth outlet 181, thereby increasing or decreasing the concentration of gas from third gas source 130 in the gas flows passing across first outside, second outside, first middle, and second middle portions of a substrate.

In yet another embodiment, gas delivery system 100 may be adapted to a gas interface such as gas interface 875 in FIG. 8 by coupling third outlet 173 to middle inlet port 945, coupling fourth outlet 180 to center inlet port 940, and coupling fifth outlet 181 to outer inlet port 950. In this embodiment, fourth flow controller 134 may be used to alter the concentration of gas from third gas source 130 passing through third outlet 173, thereby increasing or decreasing the concentration of gas from third gas source 130 in the gas flow passing across a middle annular portion of a substrate. Similarly, fourth flow controller 134 may also be used to alter the concentration of gas from third gas source 130 passing through fourth outlet 180 and fifth outlet 181, thereby increasing or decreasing the concentration of gas from third gas source 130 in the gas flow passing across a central portion and outer annular portions of a substrate.

Gas delivery system 100 may also include a variety of inline filters, purifiers, pressure transducers, and other such devices as are commonly used on substrate processing systems. These types of components have been omitted for illustrative purposes so as to not obscure the description of the present invention.

Experimental Data

In the embodiment described above, hydrogen (H₂), dichlorosilane (SiH₂Cl₂), and a 10% mixture of germane (GeH₄) in hydrogen (H₂) may be pre-mixed and distributed among inner and outer injection zones of a deposition chamber in order to deposit a layer of epitaxial SiGe onto the surface of a substrate. Referencing FIG. 1, first gas source 110 may contain hydrogen, second gas source 120 may contain dichlorosilane, and third gas source 130 may contain a 10% mixture of germane in hydrogen. First inlet port 106 and second inlet port 107 may direct process gases into a process chamber and across an outer periphery of a substrate, and third inlet port 108 may direct process gasses into a process chamber and across a central portion of a substrate. First metering valve 178 and second metering valve 179 may be adjusted to a fully open setpoint, and isolation valves 113, 123, 133, and 135 may be configured to an ON position, thereby allowing hydrogen, dichlorosilane, and the 10% mixture of germane in hydrogen to flow from gas sources 110, 120, and 130, respectively. First flow controller 112 may be adjusted to flow 30 slm of hydrogen, second flow controller 122 may be adjusted to flow 0.2 slm of dichlorosilane, and third flow controller 132 may be adjusted to flow 0.03 slm of the 10% mixture of germane in hydrogen. In this particular embodiment, fourth gas source 140 and fifth gas source 150 may not be utilized, and isolation valves 145, 155, 143, 153, 157, and 159 may be configured to an OFF condition.

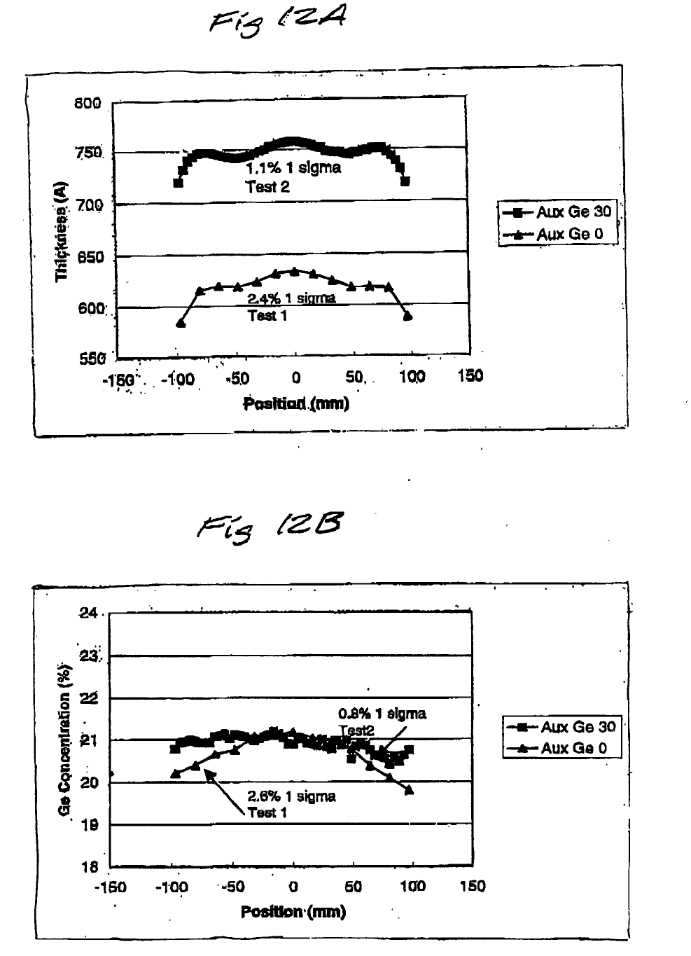

FIG. 12A shows examples of deposited SiGe film thickness uniformity across Test 1 and Test 2 substrates, each substrate comprising a 200 mm diameter silicon wafer. FIG. 12B shows examples of Ge concentration within the deposited SiGe film across the same substrates.

For the Test 1 substrate, isolation valve 137 and isolation valve 139 were each configured to an OFF condition during substrate processing. As shown in FIGS. 12A and 12B, both SiGe thickness and Ge concentration are lower at the edges of the Test 1 substrate than in the center. The SiGe thickness uniformity and Ge concentration uniformity for 3 mm edge exclusion (1-sigma deviation) for the Test 1 substrate are approximately 2.4% and 2.6%, respectively.

As previously discussed, the thickness and concentration uniformity of a deposited SiGe film across the surface of a substrate may each be altered by varying the temperature of different portions of the substrate. However, this method cannot be used to improve thickness and concentration uniformities simultaneously. Increasing the temperature across an outer periphery of a substrate will increase the edge thickness of a deposited SiGe layer relative to the thickness at the center due to increased SiGe growth rate at higher temperatures. However, the Ge concentration at the outer periphery of the substrate will decrease relative to the Ge concentration at the center because Ge incorporation within a deposited film decreases as temperature increases, assuming all other process conditions are fixed.

For the Test 2 substrate, isolation valve 137 was configured to an ON condition, isolation valve 139 was configured to an OFF condition, and the flow of the 10% mixture of germane in hydrogen through third flow controller 132 was 0.03 slm. As demonstrated by the Test 2 substrate data in FIGS. 12A and 12B, this method allows both the SiGe thickness and Ge concentration uniformities to be improved simultaneously such that the SiGe thickness uniformity and Ge concentration uniformity for 3 mm edge exclusion (1-sigma deviation) for the Test 1 substrate are approximately 1.1% and 0.9%, respectively. The Ge concentration at the outer periphery of the substrate is increased relative to the center of the substrate because the concentration of Ge directed to first inlet port 106 and second inlet port 107 was increased. The thickness uniformity is similarly improved because increasing the Ge concentration increases the SiGe growth rate.

In the foregoing specification, the invention has been described with reference to specific exemplary embodiments thereof. However, it should be evident to one skilled in the art that various modifications and changes may be made without departing from the broader spirit and scope of the invention as set forth in the appended claims. Accordingly, the specification and drawings are to be regarded in an illustrative rather than a restrictive sense.

We claim:

1. A fluid delivery system for providing processing fluids to a substrate processing system, the fluid delivery system comprising:
a first conduit for coupling a first fluid to the substrate processing system;
a first flow controller for controlling the flow of the first fluid through the first conduit;
a second conduit for coupling a second fluid to the substrate processing system;
a second flow controller for controlling the flow of the second fluid through the second conduit;
a third conduit for coupling the second fluid to the substrate processing system; and
a third flow controller for controlling the flow of the second fluid through the third conduit.

2. The fluid delivery system of claim 1, wherein the first fluid is a processing fluid and the second fluid is an inert fluid.

3. The fluid delivery system of claim 2, wherein the first fluid comprises one of monosilane, dichlorosilane, and trichlorosilane and the second fluid comprises hydrogen.

4. The fluid delivery system of claim 1, wherein the first fluid and the second fluid are each processing fluids.

5. The fluid delivery system of claim 1, wherein the first fluid comprises one of monosilane, dichlorosilane, and trichlorosilane and the second fluid comprises germane.

6. The fluid delivery system of claim 1, wherein the first flow controller, the second flow controller, and the third flow controller are computer controlled mass flow controllers controlled by input signals generated by a system controller.

7. A fluid delivery system for providing processing fluids to a substrate processing system, the fluid delivery system comprising:
a first manifold having a first inlet, a first outlet, and a second outlet, wherein the first outlet and the second outlet are coupled to the substrate processing system;
a first conduit for coupling a first fluid to the first inlet;
a first flow controller for controlling the flow of the first fluid through the first conduit;
a second conduit for coupling a second fluid to the first inlet;
a second flow controller for controlling the flow of the second fluid through the second conduit;
a second manifold having a second inlet, a third outlet, and a fourth outlet, wherein the second inlet is coupled to the second conduit, the third outlet is coupled to the first outlet, and the fourth outlet is coupled to the second outlet; and
a third flow controller for controlling the flow of the second fluid through the second manifold.

8. The fluid delivery system of claim 7, wherein the second inlet is coupled to the second conduit upstream of the second flow controller.

9. The fluid delivery system of claim 7, further comprising:
a first isolation valve for controlling the flow of processing fluids through the third outlet; and
a second isolation valve for controlling the flow of processing fluids through the fourth outlet.

10. The fluid delivery system of claim 9, wherein the first isolation valve and the second isolation valve are structured and arranged such that each valve may be opened and closed independently.

11. The fluid delivery system of claim 7, further comprising:
a third isolation valve coupled to the first conduit upstream of the first flow controller;
a fourth isolation valve coupled to the first conduit downstream of the first flow controller;
a fifth isolation valve coupled to the second conduit upstream of the second flow controller;
a sixth isolation valve coupled to the second conduit downstream of the second flow controller;
a seventh isolation valve coupled to the second inlet upstream of the third flow controller; and
an eighth isolation valve coupled to the second inlet downstream of the third flow controller.

12. The fluid delivery system of claim 11, wherein the first isolation valve, second isolation valve, third isolation valve, fourth isolation valve, fifth isolation valve, sixth isolation valve, seventh isolation valve, and eighth isolation valve are each controlled by input signals generated by a system controller.

13. The fluid delivery system of claim 7, wherein the first flow controller, the second flow controller, and the third flow controller are computer controlled mass flow controllers controlled by input signals generated by a system controller.

14. The fluid delivery system of claim 7, wherein the first fluid is a processing fluid and the second fluid is an inert fluid.

15. The fluid delivery system of claim 7, wherein the first fluid and the second fluid are each processing fluids.

16. The fluid delivery system of claim 15, wherein the first fluid comprises one of monosilane, dichlorosilane, and trichlorosilane and the second fluid comprises germane.

17. The fluid delivery system of claim 16, wherein the first fluid comprises a mixture of one of monosilane, dichlorosilane, and trichlorosilane with hydrogen.

18. The fluid delivery system of claim 16, wherein the second fluid comprises a mixture of germane and hydrogen.

19. The fluid delivery system of claim 7, further comprising a first metering valve coupled to the first outlet and a second metering valve coupled to the second outlet, wherein the first metering valve and the second metering valve may be adjusted to proportion the flow of fluids through the first outlet and the second outlet.

20. The fluid delivery system of claim 19 wherein the first metering valve and the second metering valve are needle valves.

21. A fluid delivery system for providing processing fluids to a substrate processing system, the fluid delivery system comprising:
a first manifold having a first inlet, a first outlet, and a second outlet, wherein the first outlet and the second outlet are coupled to the substrate processing system;
a first conduit for coupling a first fluid to the first inlet;
a first flow controller for controlling the flow of the first fluid through the first conduit;
a second conduit for coupling a second fluid to the first inlet;
a second flow controller for controlling the flow of the second fluid through the second conduit;
a third conduit for coupling a third fluid to the first inlet;
a third flow controller for controlling the flow of the third fluid through the third conduit;
a second manifold having a second inlet, a third outlet, and a fourth outlet, wherein the second inlet is coupled to the second conduit, the third outlet is coupled to the first outlet, and the fourth outlet is coupled to the second outlet;
a fourth flow controller for controlling the flow of the second fluid through the second manifold;
a third manifold having a third inlet, a fifth outlet, and a sixth outlet, wherein the third inlet is coupled to the third conduit, the fifth outlet is coupled to the first outlet, and the sixth outlet is coupled to the second outlet; and
a fifth flow controller for controlling the flow of the third fluid through the third manifold.

22. The fluid delivery system of claim 21, wherein the second inlet is coupled to the second conduit upstream of the second flow controller and the third inlet is coupled to the third conduit upstream of the third flow controller.

23. The fluid delivery system of claim 21, further comprising:
a first isolation valve for controlling the flow of processing fluids through the third outlet;
a second isolation valve for controlling the flow of processing fluids through the fourth outlet;
a third isolation valve for controlling the flow of processing fluids through the fifth outlet; and
a fourth isolation valve for controlling the flow of processing fluids through the sixth outlet.

24. The fluid delivery system of claim 21, wherein the first flow controller, the second flow controller, the third flow controller, the fourth flow controller, and the fifth flow controller are computer controlled mass flow controllers controlled by input signals generated by a system controller.

25. The fluid delivery system of claim 21, wherein the first fluid is a processing fluid, the second fluid is an inert fluid, and the third fluid is a processing fluid.

26. The fluid delivery system of claim 21, wherein the first fluid comprises one of monosilane, dichlorosilane, and trichlorosilane; the second fluid comprises germane; and the third fluid comprises diborane.

27. The fluid delivery system of claim 26, wherein the first fluid comprises a mixture of one of monosilane, dichlorosilane, and trichlorosilane with hydrogen.

28. The fluid delivery system of claim 26, wherein the second fluid comprises a mixture of germane and hydrogen.

29. The fluid delivery system of claim 21, further comprising a first metering valve coupled to the first outlet and a second metering valve coupled to the second outlet, wherein the first metering valve and the second metering valve may be adjusted to proportion the flow of fluids through the first outlet and the second outlet.

30. The fluid delivery system of claim 29 wherein the first metering valve and the second metering valve are needle valves.

31. The fluid delivery system of claim 23, wherein the first isolation valve, the second isolation valve, the third isolation valve, and the fourth isolation valve each may be opened and closed independently.

32. The fluid delivery system of claim 31, wherein the first isolation valve, second isolation valve, third isolation valve, and the fourth isolation valve are each controlled by input signals received from a system controller.

33. A method of delivering processing fluids to a substrate processing system, the method comprising:
providing a first conduit for coupling a first fluid to the substrate processing system and a first flow controller for controlling the flow of the first fluid through the first conduit;
providing a second conduit for coupling a second fluid to the substrate processing system and a second flow controller for controlling the flow of the second fluid through the second conduit;
providing a third conduit for coupling the second fluid to the substrate processing system and a third flow controller for controlling the flow of the second fluid through the third conduit;
controlling the flow of the first fluid through the first conduit;
controlling the flow of the second fluid through the second conduit; and
controlling the flow of the second fluid through the third conduit.

34. A method of delivering processing fluids to a substrate processing system, the method comprising:
providing a first manifold having a first inlet, a first outlet, and a second outlet, wherein the first outlet and the second outlet are coupled to the substrate processing system;
providing a first conduit for coupling a first fluid to the first inlet and a first flow controller for controlling the flow of the first fluid through the first conduit;
providing a second conduit for coupling a second fluid to the first inlet and a second flow controller for controlling the flow of the second fluid through the second conduit;
providing a second manifold having a second inlet, a third outlet, and a fourth outlet, wherein the second inlet is coupled to the second conduit, the third outlet is coupled to the first outlet, and the fourth outlet is coupled to the second outlet;
providing a third flow controller for controlling the flow of the second fluid through the second manifold;
controlling the flow of the first fluid through the first conduit;
controlling the flow of the second fluid through the second conduit; and
controlling the flow of the second fluid through the second manifold.

35. A method of depositing a silicon-germanium film on a substrate, the method comprising:
flowing a silicon source fluid through a first manifold having a first inlet, a first outlet, and a second outlet, wherein the first outlet and the second outlet are coupled to a substrate processing chamber and wherein a first flow controller controls the flow of the silicon source fluid through the first inlet;
flowing a germanium source fluid through a conduit coupled to the first inlet, wherein a second flow controller controls the flow of the germanium source fluid through the conduit; and
flowing a germanium source fluid through a second manifold having a second inlet, a third outlet, and a fourth outlet, wherein the second inlet is coupled to the conduit, the third outlet is coupled to the first outlet, and the fourth outlet is coupled to the second outlet, and wherein a third flow controller controls the flow of the germanium source fluid through the second manifold.

36. The method of claim 33 wherein the silicon source fluid comprises one of monosilane, dichlorosilane, and trichlorosilane.

37. The method of claim 33 wherein the germanium source fluid comprises germane.

38. A process recipe for directing a substrate processing system to deliver processing fluids to a substrate processing chamber, the process recipe comprising:
instructions for controlling a first computer controlled flow controller which regulates the, flow of a first fluid through a first conduit coupling a first fluid source to the substrate processing chamber;
instructions for controlling a second computer controlled flow controller which regulates the flow of a second fluid through a second conduit coupling a second fluid source to the substrate processing chamber; and
instructions for controlling a third computer controlled flow controller which regulates the flow of the second fluid through a third conduit coupling the second fluid to the substrate processing system.

39. A process recipe for directing a substrate processing system to deliver processing fluids to a substrate processing chamber, the process recipe comprising:
instructions for controlling a first computer controlled flow controller which regulates the flow of a first fluid through a first conduit, wherein the first conduit is coupled to a first inlet of a first manifold, the first manifold having a first outlet and a second outlet coupled to the substrate processing chamber;
instructions for controlling a second computer controlled flow controller which regulates the flow of a second fluid through a second conduit, wherein the second conduit is coupled to the first inlet of the first manifold; and
instructions for controlling a third computer controlled flow controller which regulates the flow of the second fluid through a second manifold, the second manifold having a second inlet, a third outlet, and a fourth outlet, wherein the second inlet is coupled to the second conduit, the third outlet is coupled to the first outlet, and the fourth outlet is coupled to the second outlet.
